(19) United States
(12) Patent Application Publication
(10) Pub. No.: US 2006/0273366 A1
(43) Pub. Date: Dec. 7, 2006

(54) Methods of manufacturing ferroelectric capacitors and semiconductor devices

(76) Inventors: Hwa-Young Ko, Gyeonggi-do (KR); Suk-Ho Joo, Seoul (KR); Byoung-Jae Bae, Gyeonggi-do (KR); Hee-Seok Kim, Gyeonggi-do (KR); Kyung-Rae Byun, Gyeonggi-do (KR); Jin-Hwan Ham, Seoul (KR)

Correspondence Address: MYERS BIGEL SIBLEY & SAJOVEC, PO BOX 37428, RALEIGH, NC, 27627, US

(21) Appl. No.: 11/447,545

(22) Filed: Jun. 6, 2006

(30) Foreign Application Priority Data
Jun. 7, 2005 (KR) 10-2005-0048531

(51) Int. Cl. H01L 29/94

(52) U.S. Cl. 257/295

(57) ABSTRACT

In a method of manufacturing a ferroelectric capacitor, a lower electrode layer is formed on a substrate. The lower electrode layer includes at least one lower electrode film. A ferroelectric layer is formed on the lower electrode layer, and then an upper electrode layer is formed on the ferroelectric layer. A hard mask structure is formed on the upper electrode layer. The hard mask structure includes a first hard mask and a second hard mask. An upper electrode, a ferroelectric layer pattern and a lower electrode are formed by partially etching the upper electrode layer, the ferroelectric layer and the lower electrode layer using the hard mask structure. The hard mask structure may prevent damage to the ferroelectric layer and may enlarge an effective area of the ferroelectric capacitor so that the ferroelectric capacitor may have enhanced electrical and ferroelectric characteristics.

### CROSS REFERENCE TO RELATED APPLICATION

This application claims priority under 35 USC § 119 to Korean Patent Application No. 10-2005-0048531 filed on Jun. 7, 2005, the content of which is incorporated herein by reference in its entirety.

### FIELD OF THE INVENTION

The present invention relates methods of manufacturing integrated circuits and, more particularly, to methods of manufacturing ferroelectric capacitors and methods of manufacturing semiconductor devices.

### BACKGROUND OF THE INVENTION

Semiconductor memory devices are generally divided into volatile semiconductor memory devices, such as dynamic random access memory (DRAM) devices and static random access memory (SRAM) devices, and nonvolatile semiconductor memory devices such as erasable programmable read-only memory (EPROM) devices, electrically erasable programmable read-only memory (EEPROM) devices and flash memory devices. A volatile semiconductor memory device loses data stored therein when power is turned off, whereas a nonvolatile semiconductor memory device can maintain data stored therein even after power is turned off.

A ferroelectric random access memory (FRAM) device has a volatile characteristic, such a RAM device, and also, a nonvolatile characteristic like a ROM device. Additionally, the FRAM device may be operated with a voltage lower than that of the EPROM device or the EEPROM device, and data stored in the FRAM device may be maintained for a long storage time.

Ferroelectric materials such as PZT [(Pb, Zr)TiO3] or SBT (SrBi2Ta2O9) have been used in FRAM devices. A ferroelectric layer of PZT is formed at a relatively low temperature of below about 650° C. The ferroelectric layer of PZT has a large polarization. However, the ferroelectric layer of PZT generally has poor fatigue characteristics and also includes an environmentally harmful ingredient, such as lead (Pb). A ferroelectric layer of SBT has excellent fatigue characteristics, and also has a polarization-voltage (P-V) hysteresis that does not imprint in a specific direction. However, the ferroelectric layer of SBT is formed through a thermal treatment at a high temperature of above about 800° C.

Methods of manufacturing an FRAM device including a ferroelectric layer are disclosed in Korean Laid-Open Patent Publication No. 2001-113271, Korean Laid-Open Patent Publication No. 2001-4306, and U.S. Patent Application Publication No. 2004/0175954.

FIGS. 1A to 1C are cross-sectional views illustrating a method of manufacturing a conventional ferroelectric capacitor.

Referring to FIG. 1, after an insulation layer 15 of oxide is formed on a semiconductor substrate 10, the insulation layer 15 is partially etched by a photolithography process to thereby form a hole through the insulation layer 15. The hole exposes a contact region (not shown) formed at an upper portion of the substrate 10.

After a conductive layer is formed on the insulation layer 15 to fill up the hole, a pad 25 is formed in the hole by partially removing the conductive layer until the insulation layer 15 is exposed.

A first lower electrode layer 30 and a second lower electrode layer 35 are sequentially formed on the insulation layer 15 and the pad 25. The first lower electrode layer 30 is formed using metal nitride, and the second lower electrode layer 35 is formed using metal.

A ferroelectric layer 40 is formed on the second lower electrode layer 35, and then an upper electrode layer 45 is formed on the ferroelectric layer 40. The ferroelectric layer 40 is formed using a ferroelectric material such as PZT or SBT. The upper electrode layer 45 includes metal oxide or metal.

A hard mask layer 50 is formed on the upper electrode layer 45. Since the hard mask layer 50 is formed using nitride, both the hard mask layer 50 and the first lower electrode layer 30 include nitride.

Referring to FIG. 1B, after a photoresist pattern (not shown) is formed on the hard mask layer 50, the hard mask layer 50 is patterned using the photoresist pattern as an etching mask so that a hard mask 51 is formed on the upper electrode layer 45.

Using the hard mask 51 as an etching mask, the upper electrode layer 45 and the ferroelectric layer 40 are successively etched, thereby forming a ferroelectric layer pattern 60 and an upper electrode 55 on the second lower electrode layer 35.

Referring to FIG. 1C, the second lower electrode layer 35 is patterned using the hard mask 51 so that a second lower electrode layer pattern 65 is formed on the first lower electrode layer 30.

A ferroelectric capacitor 80 is thereby formed on the insulation layer 15 and the pad 25 after the first lower electrode layer 30 is patterned to form a first lower electrode layer pattern 70, and while removing the hard mask 51. The ferroelectric capacitor 80 includes first and the second lower electrode layer patterns 70 and 65, the ferroelectric layer pattern 60, and the upper electrode 55.

According to the method of forming the ferroelectric capacitor 80, the ferroelectric capacitor 80 may have a sidewall inclined by a relatively low angle a because the upper electrode layer 45, the ferroelectric layer 40, and the second lower electrode layer 35 are all etched using the hard mask 50. Thus, the ferroelectric capacitor 80 may have an effective area that is reduced by the etched areas of the upper electrode layer 45, the ferroelectric layer 40, and the second lower electrode layer 35 as follows.

FIG. 2 is an electron microscopic picture showing a cross-section of a conventional ferroelectric capacitor.

Referring to FIGS. 1C and 2, in the etching process for forming the upper electrode 55, the ferroelectric layer pattern 60 and the second lower electrode layer pattern 65 using the hard mask 51 of nitride, sidewalls of the upper electrode layer 45, the ferroelectric layer 40 and the second lower electrode layer 35 are gradually etched so that a sidewall of the ferroelectric capacitor 80 may have a low angle α of below about 60° relative to the substrate 10 although the upper electrode layer 45, the ferroelectric layer 40 and the second lower electrode layer 35 have initial sidewalls inclined by high angles of about 80°. When the first lower electrode layer pattern 70 is formed, the ferroelectric capacitor 80 may include the sidewall that has a slightly increased inclination angle. However, since the sidewalls of the upper electrode 55, the ferroelectric layer pattern 60 and the second lower electrode layer pattern 65 have the low angles a as described above, the ferroelectric capacitor 80 may substantially have a sidewall inclined by the low angle a of below about 600. In particular, when the ferroelectric layer 40 is etched by a high temperature etching process, the hard mask 51 of nitride may not sufficiently protect the ferroelectric layer pattern 60 in the high temperature etching process. Therefore, the ferroelectric capacitor 80 may have a sidewall inclined by the low angle a and also the ferroelectric layer pattern 60 may be damaged in the high temperature etching process. As a result, the ferroelectric capacitor 80 may have a reduced effective area and correspondingly degraded electrical and ferroelectric characteristics. For example, an amount of charges accumulated in the ferroelectric capacitor 80 may be greatly reduced and polarization characteristics such as a 2Pr value of the ferroelectric capacitor 80 may be considerably decreased, thereby deteriorating a data sensing margin of the ferroelectric capacitor 80. Further, when the ferroelectric layer pattern 60 has the etched damage, a leakage current from the ferroelectric layer pattern 60 may be greatly increased and the ferroelectric capacitor 80 may have deteriorated data retention characteristics. Accordingly, the ferroelectric capacitor 80 may have considerably deteriorated electrical and ferroelectric characteristics.

### SUMMARY OF THE INVENTION

Some embodiments of the present invention provide methods of manufacturing a ferroelectric capacitor which may have an increased effective area and related enhanced electrical and ferroelectric characteristics.

Some other embodiments of the present invention provide methods of manufacturing a semiconductor device that includes the ferroelectric capacitor.

According to one embodiment of the present invention, a method of manufacturing the ferroelectric capacitor includes forming a lower electrode layer on a substrate. The lower electrode layer includes at least one lower electrode film. A ferroelectric layer is formed on the lower electrode layer. An upper electrode layer is formed on the ferroelectric layer. A hard mask structure is formed on the upper electrode layer. The hard mask structure includes a first hard mask and a second hard mask. An upper electrode, a ferroelectric layer pattern and a lower electrode are formed by partially etching the upper electrode layer, the ferroelectric layer, and the lower electrode layer using the hard mask structure as an etching mask.

In a further embodiment of the present invention, the lower electrode layer may be formed by forming a first lower electrode film on the substrate, and by forming a second lower electrode film on the first lower electrode film.

In a further embodiment of the present invention, the first lower electrode film may be formed using at least one selected from the group consisting of titanium aluminum nitride, aluminum nitride, titanium nitride, titanium silicon nitride, tantalum nitride, and tantalum silicon nitride, and the second lower electrode film may be formed using at least one selected from the group consisting of iridium, platinum, ruthenium, palladium, and gold, which can be used alone or as a combination thereof.

In a further embodiment of the present invention, the formation of the lower electrode layer may include forming a third lower electrode film on the second lower electrode film.

In a further embodiment of the present invention, the third lower electrode film may be formed using strontium ruthenium oxide (SRO), strontium titanium oxide (STO), lanthanum nickel oxide (LNO), and/or calcium ruthenium oxide (CRO).

In a further embodiment of the present invention, before forming the lower electrode layer, an insulation structure may be formed on the substrate, and then a hole may be formed through the insulation structure. In addition, a pad may be formed to fill the hole.

In a further embodiment of the present invention, the lower electrode layer may be formed by forming a first lower electrode film on the pad to completely fill the hole, and by forming a second lower electrode film on the first lower electrode film and the insulation structure.

In a further embodiment of the present invention, the ferroelectric layer may be formed using at least one selected from the group consisting of PZT [(Pb, Zr)TiO3], SBT (SrBi2Ta2O9), BLT [(Bi, La)TiO3], PLZT [Pb(La, Zr)TiO3], and BST [(Ba, Sr)TiO3]. Alternatively, the ferroelectric layer may be formed using PZT, SBT, BLT, PLZT, and/or BST doped with calcium, lanthanum, manganese, and/or bismuth.

In a further embodiment of the present invention, the upper electrode layer may be formed using at least one selected from the group consisting of iridium, platinum, ruthenium, platinum-manganese alloy, iridium-ruthenium alloy, iridium oxide, strontium ruthenium oxide (SRO), strontium titanium oxide (STO), lanthanum nickel oxide (LNO), and calcium ruthenium oxide (CRO).

In a further embodiment of the present invention, the upper electrode layer may be formed by forming a first upper electrode film on the ferroelectric layer, and by forming a second upper electrode film on the first upper electrode film.

In a further embodiment of the present invention, the first upper electrode film may be formed using at least one selected from the group consisting of strontium ruthenium oxide (SRO), strontium titanium oxide (STO), lanthanum nickel oxide (LNO), and calcium ruthenium oxide (CRO). The second upper electrode film may be formed using at least one selected from the group consisting of iridium, platinum, ruthenium, palladium, and gold.

In a further embodiment of the present invention, the hard mask structure may be formed by forming a first hard mask layer on the upper electrode layer, by forming a second hard mask layer on the first hard mask layer, and by forming the first and the second hard masks on the upper electrode layer by partially etching the first and the second hard mask layers.

In a further embodiment of the present invention, the first hard mask layer may be formed using at least one selected from the group consisting of strontium ruthenium oxide (SRO), strontium titanium oxide (STO), lanthanum nickel oxide (LNO), calcium ruthenium oxide (CRO), silicon nitride, and silicon oxynitride.

In a further embodiment of the present invention, the first hard mask layer may be formed by a sputtering process, a chemical vapor deposition (CVD) process, an atomic layer deposition (ALD) process, and/or a pulse laser deposition (PLD) process.

In a further embodiment of the present invention, the second hard mask layer may be formed using at least one selected from the group consisting of silicon nitride, silicon oxide, polysilicon, and silicon oxynitride.

In a further embodiment of the present invention, the second hard mask layer may be formed by a CVD process, an ALD process, a PLD process, and/or a plasma enhanced chemical vapor deposition (PECVD) process.

In a further embodiment of the present invention, a thickness ratio between the first hard mask layer and the second hard mask layer may be about 1:1 to about 1:10.

In a further embodiment of the present invention, the second hard mask layer may be removed after forming the upper electrode.

In a further embodiment of the present invention, at least a major sidewall surface of the ferroelectric capacitor may be inclined by an angle of about 80 to about 90° relative to an adjacent major upper surface of the substrate.

Some other embodiments of the present invention provide methods of manufacturing a semiconductor device. In the methods of manufacturing the semiconductor device, a lower structure is formed on a substrate. An insulation structure is formed on the lower structure. A pad contacting the lower structure is formed through the insulation structure. A lower electrode layer is formed on the pad and the insulation structure. The lower electrode includes at least one lower electrode film. A ferroelectric layer is formed on the lower electrode layer. An upper electrode layer is formed on the ferroelectric layer. A hard mask structure is formed on the upper electrode layer. The hard mask structure includes a first hard mask and a second hard mask. An upper electrode, a ferroelectric layer pattern and a lower electrode are formed by partially etching the upper electrode layer, the ferroelectric layer, and the lower electrode layer using the hard mask structure.

In a further embodiment of the present invention, the lower electrode layer may be formed by forming a first lower electrode film on the pad and the insulation structure and by forming a second lower electrode film on the first lower electrode film.

In a further embodiment of the present invention, the lower electrode layer may be formed by forming a third lower electrode film on the second lower electrode film.

In a further embodiment of the present invention, the pad may be formed by forming a hole exposing the lower structure by partially etching the insulation structure, by forming a conductive layer on the insulation structure to fill the hole, and by forming the pad to at least partially fill the hole by partially removing the conductive layer.

In a further embodiment of the present invention, the lower electrode layer may be formed by forming a first lower electrode film to completely fill the hole and by forming a second lower electrode film on the first lower electrode film and the insulation structure.

In a further embodiment of the present invention, the upper electrode layer may be formed by forming a first upper electrode film on the ferroelectric layer and by forming a second upper electrode film on the first upper electrode film.

In a further embodiment of the present invention, the hard mask structure may be formed by forming a first hard mask layer on the upper electrode layer, by forming a second hard mask layer on the first hard mask layer, and by forming the first and the second hard masks on the upper electrode layer by partially etching the first and the second hard mask layers.

According to some embodiments of the present invention, the ferroelectric capacitor may have at least a major sidewall surface that is inclined by a high angle relative to an adjacent major upper surface of the substrate to provide an increased effective area by using the hard mask structure, including the first and the second hard masks, to form the upper electrode, the ferroelectric layer pattern, and the lower electrode. The ferroelectric capacitor may thereby have enhanced ferroelectric characteristics such as improved data sensing margin, large data retention, and/or polarization retention. Additionally, since the ferroelectric layer pattern may not be damaged because of etching mask provide by the hard mask structure, the ferroelectric capacitor may have improved electrical characteristics such as a low leakage current. When the ferroelectric capacitor is employed in a semiconductor device such as the FRAM device, the semiconductor device may have an improved reliability.

### BRIEF DESCRIPTION OF THE DRAWINGS

The accompanying drawings, which are included to provide a further understanding of the present invention and are incorporated in and constitute a part of this application, illustrate example embodiment(s) of the present invention. In the drawings:

FIGS. 1A to 1C are cross-sectional views illustrating a method of manufacturing a conventional ferroelectric capacitor;

FIG. 2 is an electron microscopic picture showing a cross-section of the conventional ferroelectric capacitor;

FIGS. 3A and 3B are flow charts illustrating a method of manufacturing a ferroelectric capacitor in accordance with some embodiments of the present invention;

FIGS. 4A to 4G are cross-sectional views illustrating a method of manufacturing a ferroelectric capacitor in accordance with some embodiments of the present invention;

FIG. 5 is an electron microscopic picture showing a ferroelectric layer pattern in accordance with some embodiments of the present invention;

FIG. 6 is an electron microscopic picture showing a ferroelectric capacitor in accordance with some embodiments of the present invention;

FIGS. 7A to 7D are cross-sectional views illustrating a method of manufacturing a ferroelectric capacitor in accordance with some embodiments of the present invention;

FIGS. 8A to 8C are cross-sectional views illustrating a method of manufacturing a ferroelectric capacitor in accordance with some embodiments of the present invention;

FIGS. 9A to 9E are cross-sectional views illustrating a method of manufacturing a ferroelectric capacitor in accordance with some embodiments of the present invention; and

FIGS. 10A to 10E are cross-sectional views illustrating a method of manufacturing a semiconductor device in accordance with some embodiments of the present invention.

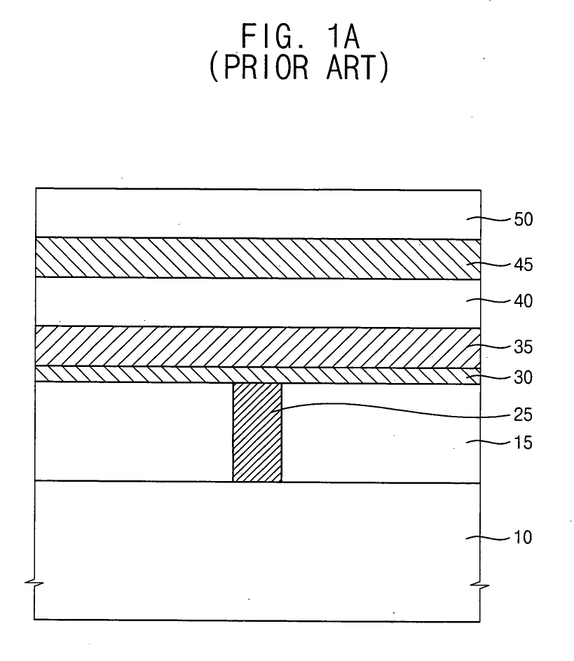

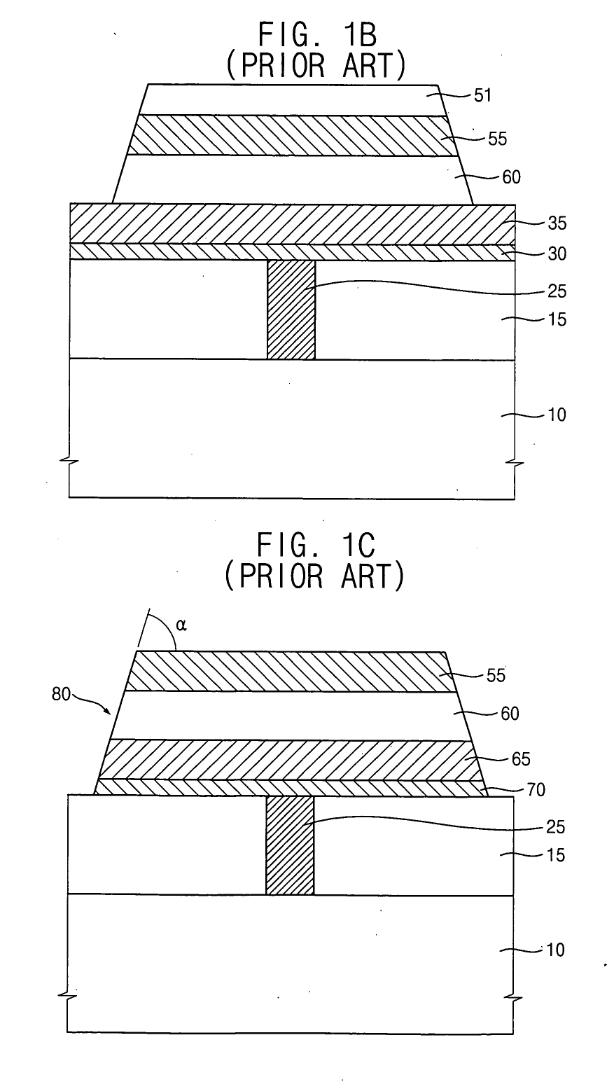

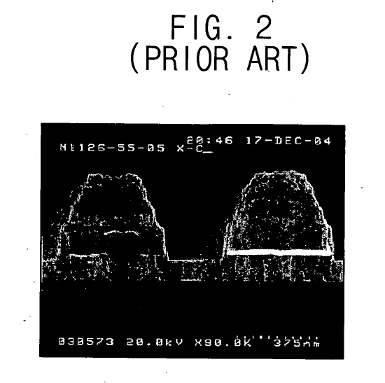

### DETAILED DESCRIPTION OF EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided SO that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Methods of Manufacturing a Ferroelectric Capacitor

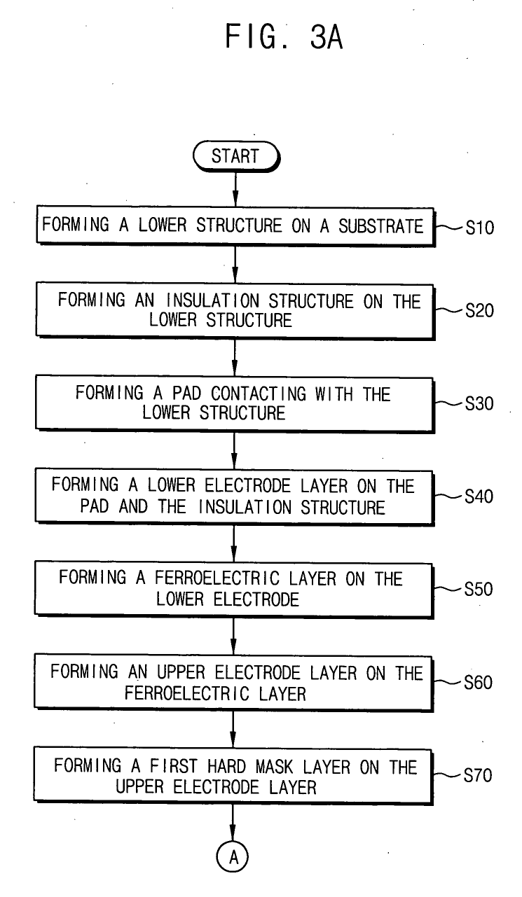

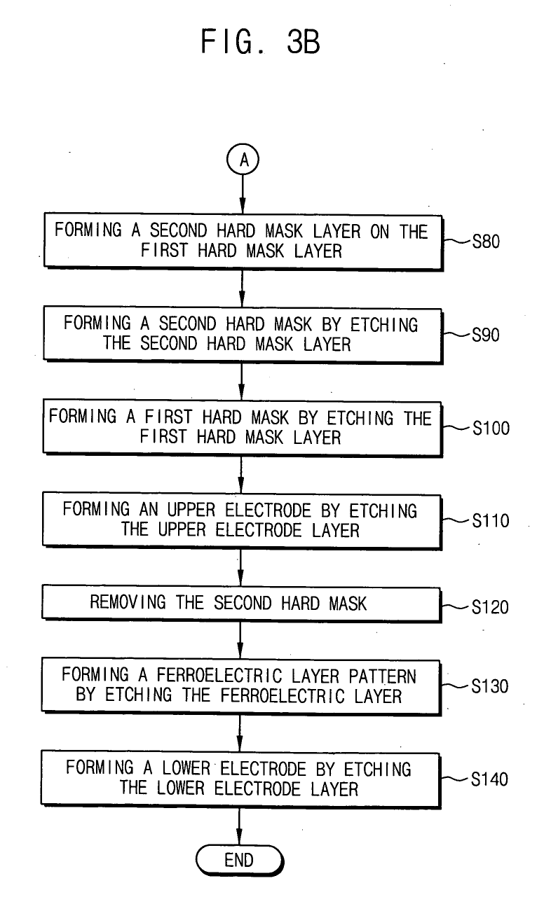

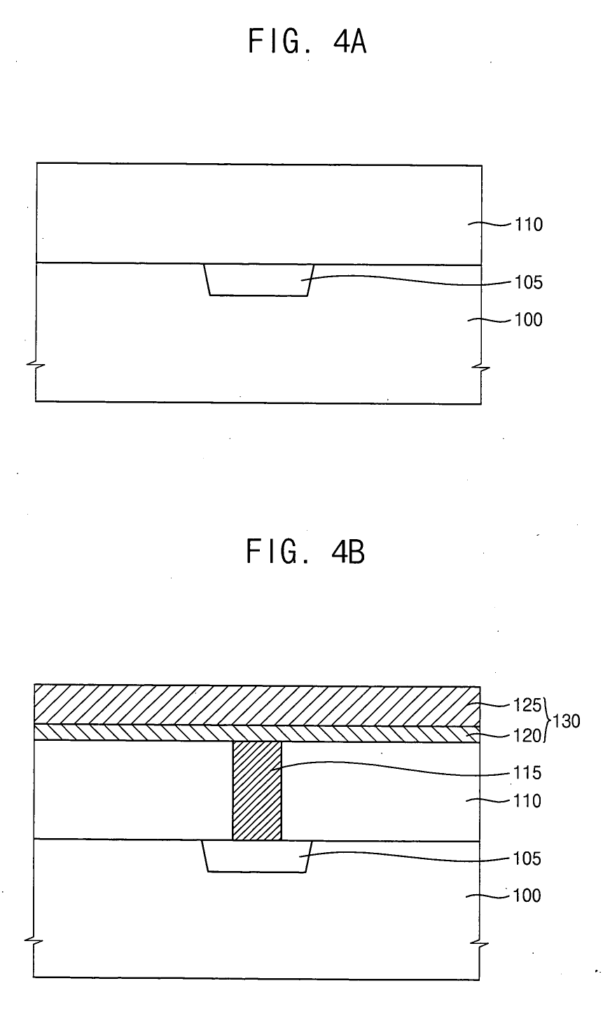

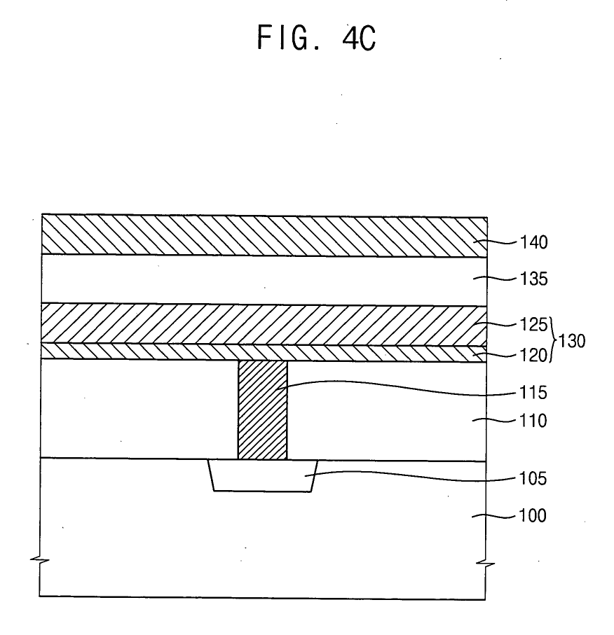

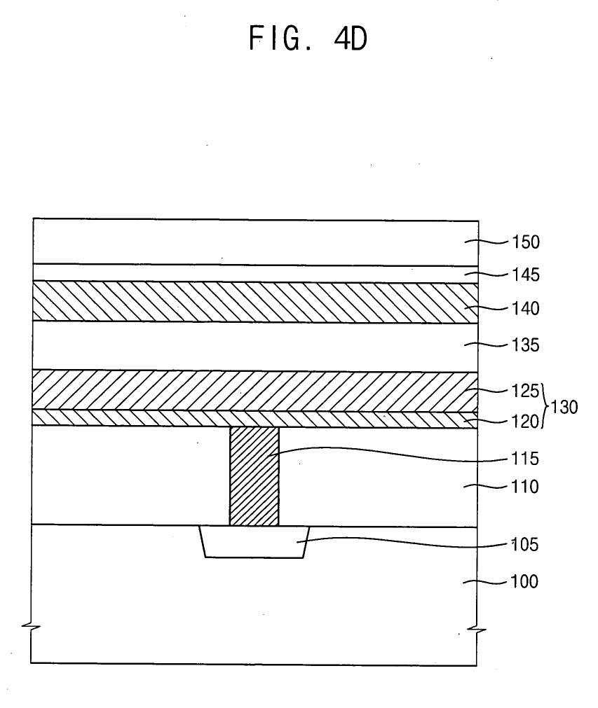

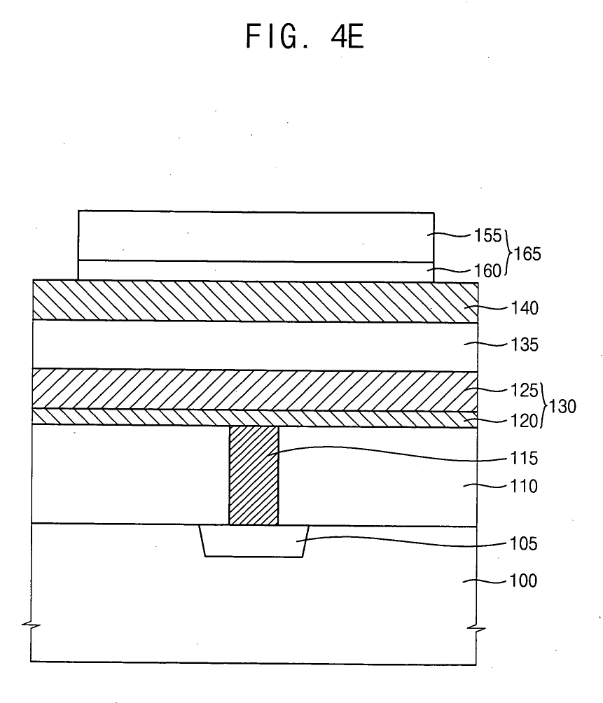

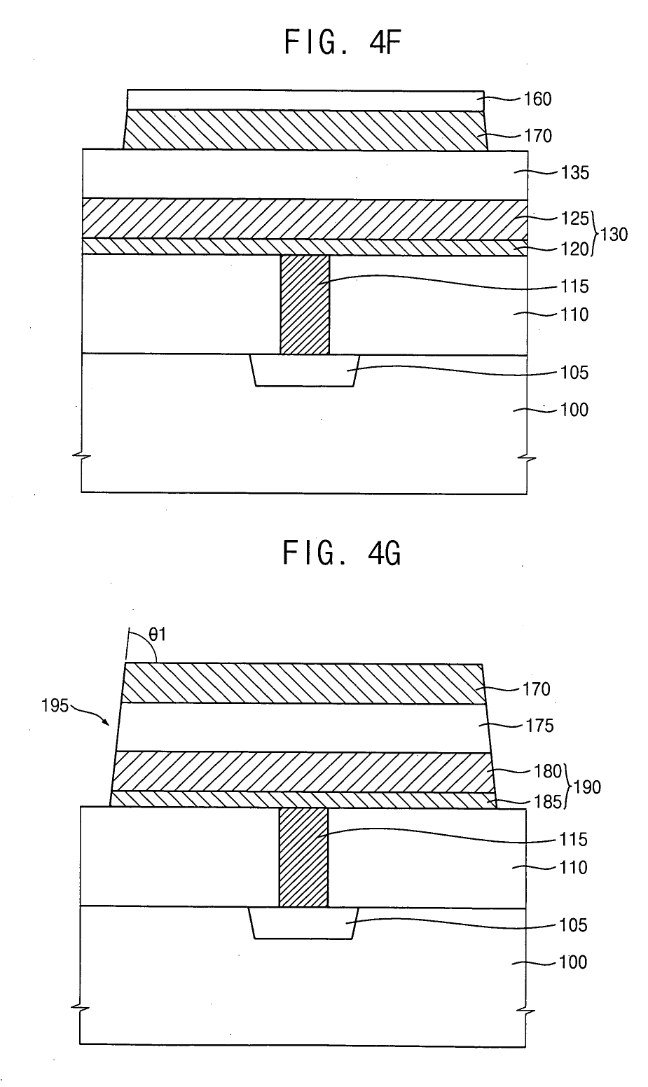

FIGS. 3A and 3B are flow charts illustrating a method of manufacturing a ferroelectric capacitor in accordance with some embodiments of the present invention. FIGS. 4A to 4G are cross-sectional views illustrating a method of manufacturing a ferroelectric capacitor in accordance with some embodiments of the present invention.

Referring to FIGS. 3A to 4A, a lower structure 105 is formed on a substrate 100 in block S10. The substrate 100 may include a silicon wafer, a silicon-on-insulator (SOI) substrate, a single crystalline metal oxide substrate, etc. For example, the substrate 100 includes a single crystalline aluminum oxide (Al₂O₃) substrate, a single crystalline strontium titanium oxide (SrTiO₃; STO) substrate, a single crystalline magnesium oxide (MgO) substrate, etc. The lower structure 105 may include a contact region, a pad, a plug, a conductive wiring, a conductive pattern, a gate structure and/or a transistor.

In block S20, an insulation structure 110 is formed on the substrate 100 to cover the lower structure 105. The insulation structure 110 electrically insulates a lower electrode 190 (see FIG. 4G) from the lower structure 105. The insulation structure 110 may include at least one insulation layer or at least one insulating interlayer. The insulation structure 110 may be formed using an oxide, a nitride and/or an oxynitride. For example, the insulation structure 110 is formed using boro-phosphor silicate glass (BPSG), phosphor silicate glass (PSG), undoped silicate glass (USG), spin on glass (SOG), flowable oxide (FOX), tetraethylorthosilicate (TEOS), plasma enhanced-TEOS (PE-TEOS), high density plasma-chemical vapor deposition (HDP-CVD) oxide, silicon nitride and/or silicon oxynitride. Additionally, the insulation structure 110 may be formed by a chemical vapor deposition (CVD) process, a plasma enhanced chemical vapor deposition (PECVD) process, an atomic layer deposition (ALD) process, an HDP-CVD process, etc.

Referring to FIGS. 3A and 4B, after a hole exposing the lower structure 105 is formed through the insulation structure 110 by partially etching the insulation structure 110, a conductive layer is formed on the insulation structure 110 to fill up the hole. The conductive layer may be formed using polysilicon doped with impurities, a metal and/or a metal nitride. For example, the conductive layer is formed using tungsten (W), aluminum (Al), copper (Cu), titanium (Ti), tungsten nitride (WN), aluminum nitride (AlN), titanium nitride (TiN), etc. These can be used alone or in a mixture thereof. The conductive layer may be formed by a sputtering process, a CVD process, an ALD process, a pulse laser deposition (PLD) process, etc.

In block S30, a pad 115 filling up the hole is formed on the lower structure 105 by partially removing the conductive layer until the insulation structure 110 is exposed. The conductive layer may be partially removed by an etch back process, a chemical mechanical polishing (CMP) process or a combination process of CMP and etch back.

A lower electrode layer 130 is formed on the pad 115 and the insulation structure 110 in block S40. The lower electrode layer 130 includes a first lower electrode film 120 and a second lower electrode film 125 sequentially formed on the pad 115 and the insulation structure 110.

The first lower electrode film 120 may have a thickness of about 50 to about 300 Å measured from an upper face of the insulation structure 110. The second lower electrode film 125 may have a thickness of about 300 to about 1,200 Å based on an upper face of the first lower electrode film 120.

The first lower electrode film 120 may be formed by depositing a conductive metal nitride on the pad 115 and the insulation structure 110 through a CVD process, an ALD process, a sputtering process, a PLD process, etc. For example, the first lower electrode film 120 is formed using titanium aluminum nitride (TiAlN), aluminum nitride, titanium nitride, titanium silicon nitride (TiSiN), tantalum nitride (TaN), tantalum silicon nitride (TaSiN), tungsten nitride, etc. These can be used alone or in a mixture thereof. The first lower electrode film 120 may be advantageously formed by depositing titanium aluminum nitride on the pad 115 and the insulation structure 110 through the ALD process.

The second lower electrode film 125 may be formed on the first lower electrode film 120 using a metal by a sputtering process, a PLD process, a CVD process, an ALD process, etc. For example, the second lower electrode film 125 is formed using iridium (Ir), platinum (Pt), ruthenium (Ru), palladium (Pd), gold (Au), etc. These can be used alone or in a mixture thereof. The second lower electrode film 125 may be advantageously formed on the first lower electrode film 120 using iridium by the sputtering process. In the process of forming the second lower electrode film 125, a reaction chamber (not shown) may have a temperature of about 20 to about 350° C. and a pressure of about 3 to about 10 mTorr after the substrate 100 having the first lower electrode film 120 is loaded into the reaction chamber. The second lower electrode film 125 may be formed under an inactive gas atmosphere by applying a power of about 300 to about 1,000W. For example, the inactive gas includes an argon (Ar) gas, a nitrogen (N₂) gas, a helium (He) gas or a mixture gas thereof.

In an example embodiment of the present invention, an adhesion layer may be formed between the insulation structure 110 and the first lower electrode film 120 to enhance the adhesion strength between the insulation structure 110 and the first lower electrode film 120. The adhesion layer may be formed on the pad 115 and the insulation structure 110 using a metal or a conductive metal nitride. For example, the adhesion layer is formed using titanium, tantalum, aluminum, tungsten, titanium nitride, tantalum nitride, aluminum nitride, tungsten nitride, etc. These can be used alone or in a mixture thereof. Additionally, the adhesion layer may be formed by a sputtering process, a CVD process, an ALD process, a PLD process, etc.

Referring to FIGS. 3A and 4C, a ferroelectric layer 135 is formed on the second lower electrode film 125 in block S50. The ferroelectric layer 135 may have a thickness of about 200 to about 1,200 Å measured from an upper face of the second lower electrode film 125. The ferroelectric layer 135 may be formed by a metal organic chemical vapor deposition (MOCVD) process, a sol-gel process, an ALD process, a CVD process, etc.

In one example embodiment of the present invention, the ferroelectric layer 135 may be formed using a ferroelectric material such as PZT[(Pb, Zr)TiO₃], SBT(SrBi₂Ta₂O₉), BLT[(Bi, La)TiO₃], PLZT[Pb(La, Zr)TiO₃], BST[(Ba, Sr)TiO₃], etc.

In another example embodiment of the present invention, the ferroelectric layer 135 may be formed using the ferroelectric material doped with a metal such as calcium (Ca), lanthanum (La), manganese (Mn), bismuth (Bi), etc.

In still another example embodiment of the present invention, the ferroelectric layer 135 may be formed using a metal oxide having a ferroelectric property. For example, the ferroelectric layer 135 is formed using titanium oxide (TiO₂), tantalum oxide (Ta₂O₅), aluminum oxide (Al₂O₃), zinc oxide (ZnO₂), hafnium oxide (HfO₂), etc.

The ferroelectric layer 135 may be advantageously formed on the second lower electrode film 125 using PZT by the MOCVD process. In the MOCVD process for forming the ferroelectric layer 135, a reaction chamber may have a temperature of about 350 to about 650° C. and a pressure of about 1.0 to about 10 Torr after the substrate 100 having the second lower electrode film 125 is loaded into the reaction chamber. The ferroelectric layer 135 may be formed in accordance with the chemical reaction between a metal organic precursor and an oxidant after the metal organic precursor and the oxidant are provided onto the substrate 100. The metal organic precursor may include a first compound containing lead (Pb), a second compound containing zirconium (Zr) and a third compound containing titanium. Alternatively, the metal organic precursor may directly include lead, zirconium and titanium. The oxidant may include oxygen (O₂), ozone (O₃), nitrogen oxide (NO₂), nitrous oxide (N₂O), etc.

In block S60, an upper electrode layer 140 is formed on the ferroelectric layer 135. The upper electrode layer 140 may be formed using a metal or a metal oxide by a sputtering process, a CVD process, an ALD process, a PLD process, etc. For example, the upper electrode layer 140 is formed using iridium, platinum, ruthenium, palladium, gold, platinum-manganese (Pt—Mn) alloy, iridium-ruthenium (Ir—Ru) alloy, iridium oxide (IrO₂), strontium ruthenium oxide (SrRuO₃; SRO), strontium titanium oxide (STO), lanthanum nickel oxide (LaNiO₃; LNO), calcium ruthenium oxide (CaRuO₃; CRO), etc. These can be used alone or in a mixture thereof. The upper electrode layer 140 may have a thickness of about 100 to about 1,200 Å measured from an upper face of the ferroelectric layer 135. In the process of forming the upper electrode layer 140, a reaction chamber may have a temperature of about 20 to about 350° C. and a pressure of about 3 to 10 mTorr after the substrate 100 having the ferroelectric layer 135 is loaded into the reaction chamber. The upper electrode layer 140 may be formed under an inactive gas atmosphere by applying a power of about 300 to about 1,000W.

In an example embodiment of the present invention, after the upper electrode layer 140 is formed on the ferroelectric layer 135, the ferroelectric layer 135 and the upper electrode layer 140 may be thermally treated by a rapid thermal process (RTP) under an atmosphere including an oxygen gas, a nitrogen gas or a mixture gas of oxygen and nitrogen. When the upper electrode layer 140 and the ferroelectric layer 135 are thermally treated, ingredients contained in the upper electrode layer 140 and the ferroelectric layer 135 may be crystallized. The upper electrode layer 140 and the ferroelectric layer 135 may be thermally treated at a temperature of about 500 to about 650° C. for about 30 seconds to about 3 minutes.

Referring to FIGS. 3A and 4D, a first hard mask layer 145 is formed on the upper electrode layer 140 in block S70. The first hard mask 145 may have a thickness of about 100 to about 300 Å measured from an upper face of the upper electrode layer 140. The first hard mask layer 145 may be formed using a material having an etching selectivity relative to the upper electrode layer 140, the ferroelectric layer 135 and the lower electrode layer 130. For example, the first hard mask layer 145 is formed using strontium ruthenium oxide (SRO), strontium titanium oxide (STO), lanthanum nickel oxide (LNO), calcium ruthenium oxide (CRO), silicon nitride, silicon oxynitride, etc. These can be used alone or in a mixture thereof. The first hard mask layer 145 may be advantageously formed using strontium ruthenium oxide (SRO). Additionally, the first hard mask 145 may be formed by a sputtering process, a CVD process, an ALD process or a PLD process.

In one example embodiment of the present invention, when the upper electrode layer 140 includes strontium ruthenium oxide (SRO), the first hard mask 145 is formed using silicon nitride, silicon oxynitride, strontium titanium oxide (STO), lanthanum nickel oxide (LNO) and/or calcium ruthenium oxide (CRO). In another example embodiment of present invention, when the upper electrode layer 140 includes iridium, platinum, ruthenium, palladium, gold, platinum-manganese alloy, iridium-ruthenium alloy or iridium oxide, the first hard mask layer 145 is formed using strontium ruthenium oxide (SRO).

Referring now to FIGS. 3B and 4D, a second hard mask layer 150 is formed on the first hard mask layer 145 in block S80. The second hard mask layer 150 may have a thickness of about 300 to about 1,000 Å measured from an upper face of the first hard mask layer 145. Accordingly, a thickness ratio between the first hard mask layer 145 and the second hard mask layer 150 may be about 1.0:1.0 to about 1.0:10. The second hard mask 150 may be formed by a CVD process, an ALD process, a PECVD process, a PLD process, etc. The second hard mask 150 may be formed using a material having an etching selectivity relative to the first hard mask layer 145, the upper electrode layer 140 and the ferroelectric layer 135. For example, the second hard mask 150 is formed using undoped polysilicon, a nitride such as silicon nitride, an oxide such as silicon oxide, or an oxynitride such as silicon oxynitride. The second hard mask layer 150 may be advantageously formed using silicon nitride.

Referring to FIGS. 3B and 4E, after a photoresist pattern is formed on the second hard mask layer 150, the second hard mask layer 150 is partially etched using the photoresist pattern as an etching mask. Thus, a second hard mask 155 is formed on the first hard mask layer 145 in block S90.

The photoresist pattern is removed from the second hard mask 155 by an ashing process and/or a stripping process, and then the first hard mask layer 145 is partially etched using the second hard mask 155 as an etching mask. Accordingly, a first hard mask 160 is formed on the upper electrode layer 140 in block S100. As a result, a hard mask structure 165 having the first and the second hard masks 160 and 155 is formed on the upper electrode layer 140. In an example embodiment of the present invention, a surface of the second hard mask 160 may be improved by a spin scrubbing process. That is, the surface of the second hard mask 160 may be polished to have an improved roughness.

In an example embodiment of the present invention, the hard mask structure 165 may be formed on the upper electrode layer 140 by sequentially etching the second hard mask layer 150 and the first hard mask layer 140 using the photoresist pattern as an etching mask.

Referring to FIGS. 3B and 4F, an upper electrode 170 is formed on the ferroelectric layer 135 by partially etching the upper electrode layer 140 using the hard mask structure 165 as an etching mask in block S110. The upper electrode 170 may have an upper portion slightly smaller than a lower portion thereof. In other words, the upper electrode 170 may have at least a major sidewall surface, or an entire sidewall surface, inclined by a high angle of about 80 to about 90° with respect to a major adjacent upper surface of the substrate 100. Since the second hard mask 155 may be somewhat consumed in the etching process for forming the upper electrode 170, the second hard mask 155 may have a reduced thickness after forming the upper electrode 170 using the hard mask structure 165.

In block 120, the second hard mask 155 is removed from the first hard mask 160 after forming the upper electrode 170 on the ferroelectric layer 135. Accordingly, only the first hard mask 160 remains on the upper electrode 170. In an example embodiment of the present invention, a surface of the first hard mask 160 may be improved by a spin scrubbing process as described above.

Referring to FIGS. 3B and 4G, in block S130, a ferroelectric layer pattern 175 is formed on the second lower electrode film 125 by partially etching the ferroelectric layer 135 using the first hard mask 160 as an etching mask. When the ferroelectric layer 135 is partially etched at a relatively low temperature, the ferroelectric layer pattern 175 may have a sidewall inclined by a relatively small angle with respect to a major adjacent upper surface of the substrate 100. To form the ferroelectric layer pattern 175 having a sidewall inclined by a high angle with respect to the substrate 100, the ferroelectric layer 135 is etched at a high temperature. For example, the ferroelectric layer 135 can be etched at a temperature of about 200 to about 400° C.

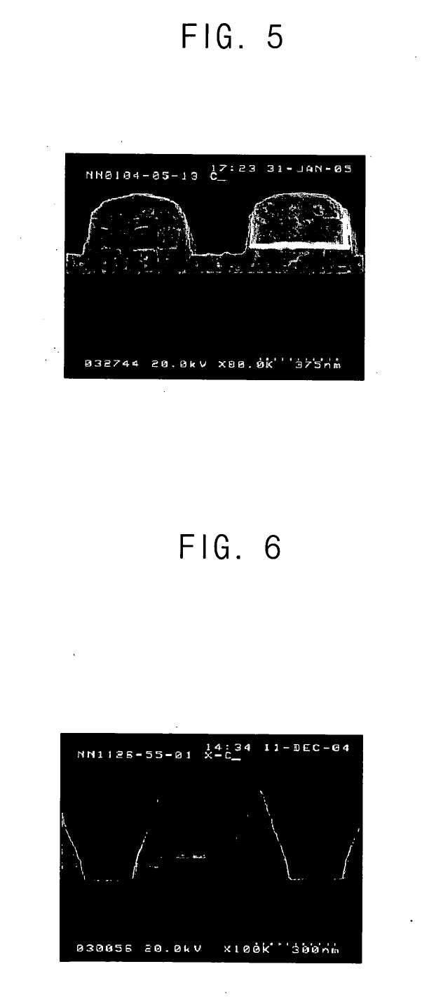

FIG. 5 is an electron microscopic picture showing a cross-section of the ferroelectric layer pattern 175 in accordance with an example embodiment of the present invention.

As shown in FIG. 5, the ferroelectric layer pattern 175 has a sidewall highly inclined by an angle of about 80 to about 90° with respect to a major adjacent upper surface of the substrate 100 when the ferroelectric layer 135 is etched using the first hard mask 160. The first hard mask 160 may effectively protect the upper electrode 170 in the etching process for forming the ferroelectric layer pattern 175 at the high temperature so that the sidewall of the upper electrode 170 substantially maintains the high angle of about 80 to about 90° with respect to the substrate 100.

In block 140, a lower electrode 190 is formed on the insulation structure 110 by sequentially patterning the second lower electrode film 125 and the first lower electrode film 120 using the first hard mask 160 as an etching mask.

When the first hard mask 160 is removed from the upper electrode 170, the ferroelectric capacitor 195 is formed over the substrate 100. The ferroelectric capacitor 195 includes the lower electrode 190, the ferroelectric layer pattern 175 and the upper electrode 170. The lower electrode 190 includes a first lower electrode film pattern 185 and a second lower electrode film pattern 180. The first lower electrode film pattern 185 is formed on the insulation structure 110 and the pad 115. The second lower electrode film pattern 180 is positioned on the first lower electrode layer pattern 185. The first lower electrode film pattern 185 may prevent oxygen atoms in the ferroelectric layer pattern 175 from diffusing into underlying structures. The second lower electrode film pattern 180 may enhance a crystallization of the ferroelectric material in the ferroelectric layer pattern 175. Further, the first lower electrode film pattern 185 may improve the adhesion strength between the insulation structure 110 and the second lower electrode film pattern 180 when the adhesion layer is not formed between the insulation structure 110 and the first lower electrode film pattern 185.

In some embodiments of the present invention, the ferroelectric layer pattern 175 and the lower electrode 190 may be formed using the second hard mask 155 and the first hard mask 160 as etching masks without removing the second hard mask 155. The second hard mask 155 may be substantially consumed when forming the ferroelectric layer 135, the second lower electrode film 125, and the first lower electrode film 120. Hence, an additional process for removing the second hard mask 155 may not be required.

FIG. 6 is an electron microscopic picture showing a cross-section of the ferroelectric capacitor 195 in accordance with an example embodiment of the present invention.

Referring to FIGS. 4G and 6, the ferroelectric capacitor 195 has a sidewall highly inclined by an angle Θ1 of about 80 to about 90° relative to the substrate 100 when the ferroelectric capacitor 195 is formed using the hard mask structure 165 having the first and the second hard masks 160 and 165. Namely, the first and the second hard masks 160 and 165 effectively protect the upper electrode 170 and the ferroelectric layer pattern 175 in the relatively long etching processes for forming the upper electrode 170, the ferroelectric layer pattern 175 and the lower electrode 190. Thus, the sidewalls of the upper electrode 170 and the ferroelectric layer pattern 175 can maintain the high angle of about 80 to about 90° with respect to the substrate 100. As a result, the ferroelectric capacitor 195 has the sidewall highly inclined by the angle Θ1 of about 80 to about 90° with respect to the substrate 100 which thereby enlarges an effective area of the ferroelectric capacitor 195. When the ferroelectric capacitor 195 has the highly inclined sidewall, a 2Pr value of the ferroelectric layer pattern 195 may be improved because an amount of charges accumulated on the ferroelectric layer pattern 175 may be increased. When polarization characteristics of the ferroelectric layer pattern 195 are enhanced, data retention characteristics or polarization retention characteristics of the ferroelectric capacitor 195 may also be improved. As a result, the ferroelectric capacitor 195 may have greatly increased ferroelectric characteristics. Further, since the first hard mask 160 effectively prevents etching damage to the ferroelectric layer pattern 175, a leakage current from the ferroelectric layer pattern 175 may be prevented and deterioration of the ferroelectric layer pattern 175 may be minimized. As a result, the ferroelectric capacitor 195 including the ferroelectric layer pattern 175 may have improved electrical characteristics.

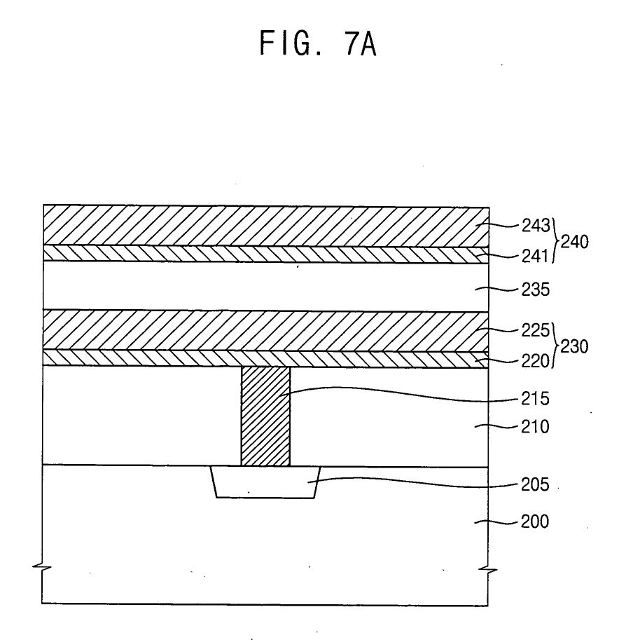

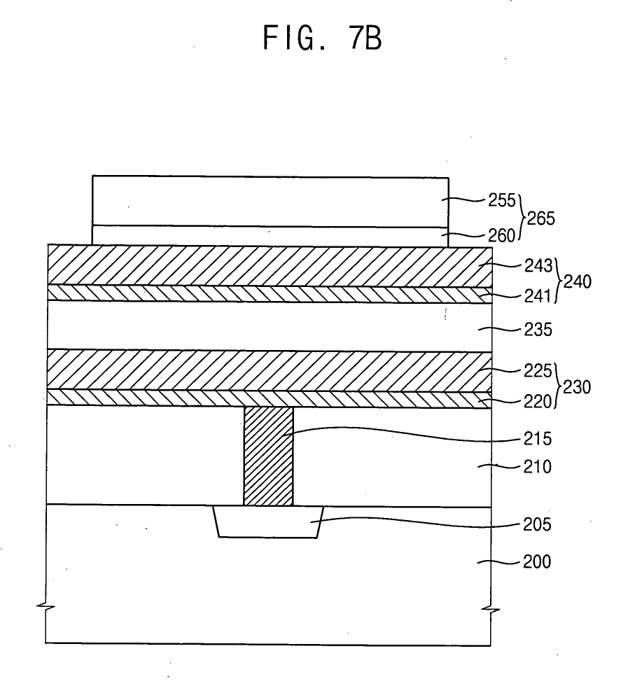

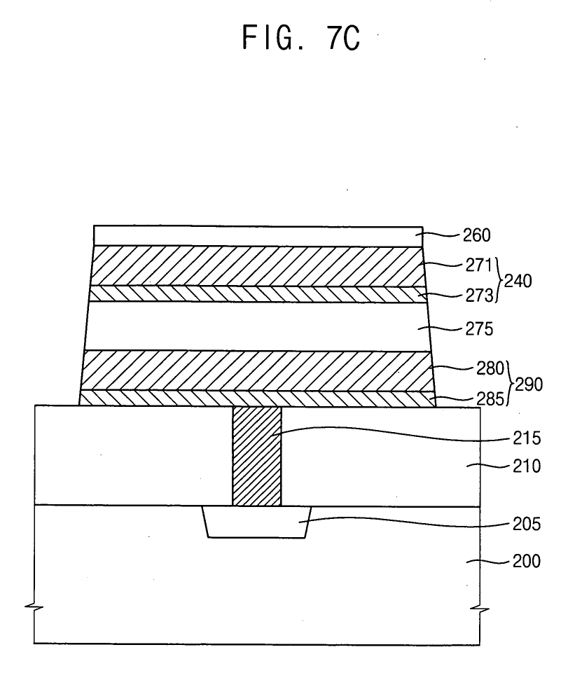

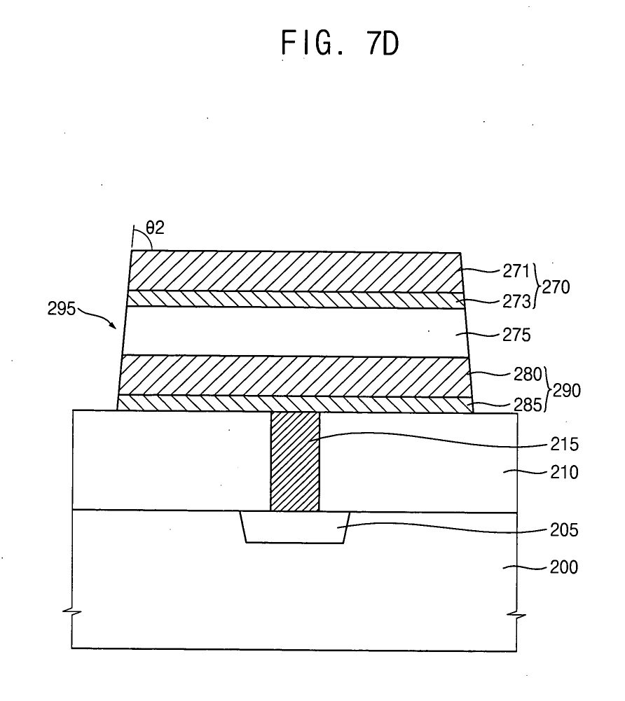

FIGS. 7A to 7D are cross-sectional views illustrating a method of manufacturing a ferroelectric capacitor in accordance with some embodiments of the present invention.

Referring to FIG. 7A, a lower structure 205 is formed on a substrate 200. The lower structure 205 may include a contact region, a pad, a plug, a conductive wiring, a conductive pattern, a gate structure and/or a transistor. The substrate 200 may include a semiconductor substrate such as a silicon wafer or an SOI substrate. Alternatively, the substrate 200 may include a single crystalline metal oxide substrate.

An insulation structure 210 is formed on the substrate 200 to cover the lower structure 205. The insulation structure 210 may include at least one insulation layer and/or at least one insulating interlayer. The insulation structure 210 electrically insulates the lower structure 205 from a lower electrode 290 (see FIG. 7C).

The insulation structure 210 is partially etched to form a hole that partially exposes the lower structure 205. A conductive layer is formed on the insulation structure 210 to fill up the hole. The conductive layer is partially removed until the insulation structure 210 is exposed, thereby forming a pad 215 buried in the hole. The pad 215 may be formed by an etch back process, a CMP process, or a combination process of CMP and etch back.

A lower electrode layer 230 is formed on the pad 215 and the insulation structure 210 by sequentially forming a first lower electrode film 220 and a second lower electrode film 225 on the pad 215 and the insulation structure 210. The first lower electrode film 220 may have a thickness of about 50 to about 300 Å measured from an upper face of the insulation structure 210, and the second lower electrode film 225 may have a thickness of about 300 to about 1,200 Å based on an upper face of the first lower electrode film 220. The first lower electrode film 220 may be formed using a conductive metal nitride, and the second lower electrode film 225 may be formed using a metal.

As described above, an adhesion layer (not shown) including a metal or a conductive metal nitride may be formed between the insulation structure 210 and the first lower electrode film 220 to improve the adhesion strength between the insulation structure 210 and the first lower electrode film 220.

A ferroelectric layer 235 is formed on the second lower electrode film 225 by a MOCVD process, a sol-gel process, an ALD process or a CVD process. The ferroelectric layer 235 may have a thickness of about 200 to about 1,200 Å measured from an upper face of the second lower electrode film 225. The ferroelectric layer 235 may be formed using a ferroelectric material, the ferroelectric material doped with a metal or a metal oxide having a ferroelectric property.

An upper electrode layer 240 is formed on the ferroelectric layer 235. The upper electrode layer 240 includes a first upper electrode film 241 and a second upper electrode film 243 sequentially formed on the ferroelectric layer 235.

The first upper electrode film 241 may have a thickness of about 10 to about 300 Å based on an upper face of the ferroelectric layer 235. The first upper electrode film 241 may be formed by depositing a metal oxide doped with a metal on the ferroelectric layer 235. The first upper electrode film 241 may be formed by a sputtering process, a CVD process, an ALD process or a PLD process. The metal oxide in the first upper electrode film 241 may include strontium ruthenium oxide (SRO), strontium titanium oxide (STO), lanthanum nickel oxide (LNO) or calcium ruthenium oxide (CRO). Additionally, the metal of the first upper electrode film 241 may include copper, lead or bismuth. The first upper electrode film 241 may be advantageously formed using strontium ruthenium oxide (SRO) doped with lead by the sputtering process. In formation of the first upper electrode film 241, a reaction chamber may have a temperature of about 20 to about 350° C. and a pressure of about 3 to about 10 mTorr after the substrate 200 having the ferroelectric layer 235 is positioned in the reaction chamber. The first upper electrode film 241 may be formed in the reaction chamber under an inactive gas atmosphere by applying a power of about 300 to about 1,000W.

The second upper electrode film 243 may have a thickness of about 300 to about 1,000 Å based on an upper face of the first upper electrode film 241. The second upper electrode film 243 may be formed by depositing a metal, a metal alloy or a metal oxide on the first upper electrode film 241. The second upper electrode film 243 may be formed by a sputtering process, a CVD process, an ALD process or a PLD process. For example, the second upper electrode film 243 is formed using iridium, platinum, ruthenium, palladium, gold, platinum-manganese alloy, iridium-ruthenium alloy, iridium oxide, etc. In the process for forming the second upper electrode film 243, a reaction chamber receiving the substrate 200 therein may have a temperature of about 20 to about 350° C. and a pressure of about 3 to about 10 mTorr. The second upper electrode film 243 may be formed in the reaction chamber under an inactive gas atmosphere by applying a power of about 300 to about 1,000W.

After forming the upper electrode layer 240 having the first and the second upper electrode films 241 and 243 on the ferroelectric layer 235, the ferroelectric layer 235 and the upper electrode layer 240 are thermally treated under an atmosphere including an oxygen gas, a nitrogen gas or a mixture gas of oxygen and nitrogen, thereby crystallizing ingredients contained in the ferroelectric layer 235 and the upper electrode layer 240. The ferroelectric layer 235 and the upper electrode layer 240 may be thermally treated by a RTP.

Referring to FIG. 7B, a first hard mask layer and a second hard mask layer are sequentially formed on the second upper electrode film 243. The first hard mask layer may have a thickness of about 100 to about 300 Å measured from an upper face of the second upper electrode film 243. The second hard mask layer may have a thickness of about 300 to about 1,000 Å based on an upper face of the first hard mask layer. The first hard mask layer may be formed by a sputtering process, a CVD process, an ALD process, a PLD process, etc. The second hard mask layer may be formed by a CVD process, a PECVD process, a PLD process, an ALD process, etc.

After a photoresist pattern is formed on the second hard mask layer, the second and the first hard mask layers are etched using the photoresist pattern as an etching mask. Thus, a hard mask structure 265 is formed on the upper electrode layer 240. The hard mask structure 265 includes a first hard mask 260 and a second hard mask 255 successively formed on the second upper electrode film 243.

The first hard mask 260 may include a material that has a high etching selectivity relative to the first and the second upper electrode films 241 and 243, the ferroelectric layer 235, and the first and the second lower electrode films 220 and 225. For example, the first hard mask 260 is formed using strontium ruthenium oxide (SRO), strontium titanium oxide (STO), lanthanum nickel oxide (LNO), calcium ruthenium oxide (CRO), silicon nitride, silicon oxynitride, etc. In an example embodiment of the present invention, the first hard mask 260 includes strontium ruthenium oxide (SRO).

The second hard mask 255 may include a material having an etching selectivity with respect to the first hard mask 260, the first and the second upper electrode films 241 and 243, and the ferroelectric layer 235. For example, the second hard mask 255 is formed using undoped polysilicon, silicon oxide, silicon nitride, silicon oxynitride, etc. In an example embodiment of the present invention, the second hard mask 255 is formed using silicon nitride.

Referring to FIG. 7C, the photoresist pattern is removed by an ashing process and/or a stripping process, and then the second and the first upper electrode films 243 and 241 are sequentially etched using the hard mask structure 265 as an etching mask, thereby forming an upper electrode 270 on the ferroelectric layer 235. The upper electrode 270 includes a first upper electrode film pattern 273 and a second upper electrode film pattern 271 successively formed on the ferroelectric layer 235. Each of the first and the second upper electrode film patterns 273 and 271 includes an upper portion slightly wider than a lower portion thereof. Hence, each of the first and the second upper electrode film patterns 273 and 271 may have at least a major sidewall surface, or an entire sidewall surface, inclined by a high angle of about 80 to about 90° relative to a major adjacent upper surface of the substrate 200.

After forming the upper electrode 270, the second hard mask 255 is removed so that only the first hard mask 260 remains on the upper electrode 270.

Using the first hard mask 260 as an etching mask, the ferroelectric layer 235 is partially etched at a relatively high temperature to thereby form a ferroelectric layer pattern 275 on the second lower electrode film 225. Since the first hard mask 260 may effectively protect the ferroelectric layer pattern 275 in the high temperature etching process, the ferroelectric layer pattern 275 may also have a sidewall inclined by a high angle of about 80 to about 90° with respect to substrate 200.

The second and the first lower electrode films 225 and 220 are sequentially etched continuously using the first hard mask 260 so that a lower electrode 290 is formed on the insulation structure 210. The lower electrode 290 includes a first lower electrode film pattern 285 and a second lower electrode film pattern 280 successively formed on the insulation structure 210. Each of the first and the second lower electrode film patterns 285 and 280 includes an upper portion slightly wider than a lower portion thereof. Thus, each of the first and the second lower electrode film patterns 285 and 280 may have a sidewall inclined by a high angle of about 80 to about 90° relative to the substrate 200.

Referring to FIG. 7D, when the first hard mask 260 is removed from the upper electrode 270, a ferroelectric capacitor 295 is formed over the substrate 200. The ferroelectric capacitor 295 includes the lower electrode 290, the ferroelectric layer pattern 275 and the upper electrode 270. Since the ferroelectric capacitor 295 is formed using the first hard mask 260 that includes the material having the high etching selectivity relative to the ferroelectric layer 235, the first lower electrode film 220 and the second lower electrode film 225, the ferroelectric capacitor 295 may also have a sidewall inclined by a high angle 02 of about 80 to about 900 relative to the substrate 200.

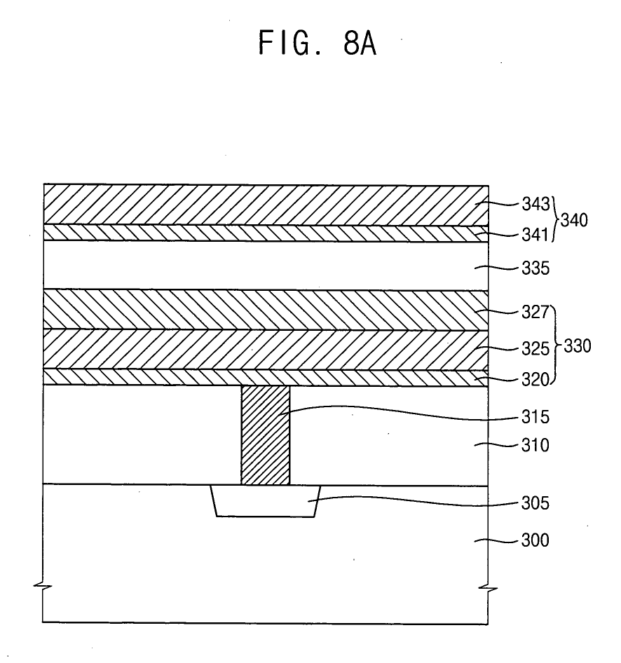

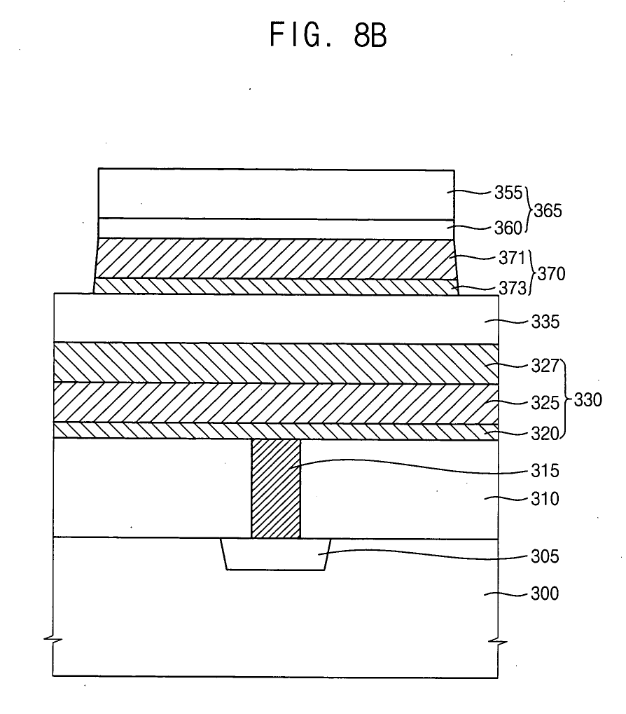

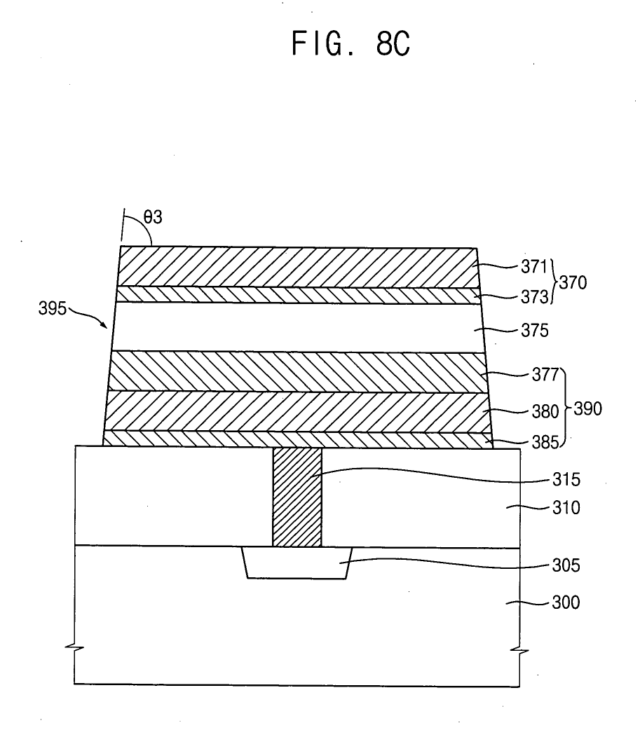

FIGS. 8A to 8C are cross-sectional views illustrating a method of manufacturing a ferroelectric capacitor in accordance with some embodiments of the present invention.

Referring to FIG. 8A, a lower structure 305 is formed on a substrate 300. The lower structure 305 may include a contact region, a conductive wiring, a conductive pattern, a pad, a plug, a gate structure and/or a transistor.

An insulation structure 310 is formed on the substrate 300 to cover the lower structure 305. The insulation structure 310 may be formed using an oxide such as PSG, USG, SOG, FOX, PE-TEOS, HDP-CVD oxide, etc. The insulation structure 310 may be formed by a CVD process, a PECVD process, an ALD process or an HDP-CVD process.

After a first photoresist pattern (not shown) is formed on the insulation structure 310, the insulation structure 310 is partially etched using the first photoresist pattern as an etching mask to form a hole that partially exposes the lower structure 305.

A conductive layer is formed on the insulation structure 310 to fill up the hole by a sputtering process, a CVD process, a PLD process or an ALD process. The conductive layer may be formed using a metal or a conductive metal nitride. For example, the conductive layer is formed using tungsten, aluminum, copper, titanium, tungsten nitride, aluminum nitride, titanium nitride, etc.

The conductive layer is partially removed by a CMP process and/or an etch back process until the insulation structure 310 is exposed, thereby forming a pad 315 in the hole. The pad 315 fills the hole and makes contact with the lower electrode 305.

A first lower electrode film 320 is formed on the insulation structure 310 and the pad 315. The first lower electrode film 320 may have a thickness of about 50 to about 300 Å based on an upper face of the insulation structure 310. The first lower electrode film 320 may be formed using a metal nitride by a CVD process, a sputtering process, a PLD process or an ALD process.

A second lower electrode film 325 is formed on the first lower electrode film 320 using iridium, platinum, ruthenium, palladium or gold by a sputtering process, a PLD process, a CVD process or an ALD process. The second lower electrode film 325 may have a thickness of about 300 to about 1,000 Å measured from an upper face of the first lower electrode film 320.

A lower electrode layer 330 is formed on the pad 315 and the insulation structure 310 by forming a third lower electrode film 327 on the second lower electrode film 325. Namely, the lower electrode layer 330 includes the first, the second and the third lower electrode films 320, 325 and 327. The third lower electrode film 327 may be formed a metal oxide doped with copper, lead or bismuth. For example, the metal oxide in the third lower electrode film 327 includes strontium ruthenium oxide (SRO), strontium titanium oxide (STO), lanthanum nickel oxide (LNO), calcium ruthenium oxide (CRO), etc. The third lower electrode film 327 may have a thickness of about 10 to about 500 Å measured from an upper face of the second lower electrode film 325. In a formation of the third lower electrode film 327, a reaction chamber in which the substrate 300 is loaded may have a temperature of about 20 to about 350° C. and a pressure of about 3 to about 10 mTorr. Additionally, the third lower electrode film 327 may be formed under an inactive gas atmosphere by applying a power of about 300 to about 1,000W. The inactive gas may include an argon gas, a nitrogen gas, a helium gas, etc.

A ferroelectric layer 335 is formed on the third lower electrode film 327 by a MOCVD process, a sol-gel process or an ALD process. The ferroelectric layer 335 may have a thickness of about 200 to about 1,000 Å based on an upper face of the third lower electrode film 327. The ferroelectric layer 335 may be formed using a ferroelectric material, a metal oxide having a ferroelectric property or a ferroelectric material doped with calcium, lanthanum, manganese or bismuth.

A first upper electrode film 341 is formed on the ferroelectric layer 335 by a sputtering process, a PLD process, a CVD process or an ALD process. The first upper electrode film 341 may be formed using a metal oxide doped with copper, lead or bismuth. For example, the metal of the first upper electrode film 341 includes strontium ruthenium oxide (SRO), strontium titanium oxide (STO), lanthanum nickel oxide (LNO), calcium ruthenium oxide (CRO), etc. The first upper electrode film 341 may have a thickness of about 10 to about 300 Å based on an upper face of the ferroelectric layer 335.

A second upper electrode film 343 is formed on the first upper electrode film 341 using a metal such as iridium, platinum, ruthenium, palladium or gold. Accordingly, an upper electrode layer 340 having the first and the second upper electrode films 341 and 343 is formed on the ferroelectric layer 335. The second upper electrode film 343 may be formed by a sputtering process, a PLD process, a CVD process or an ALD process. The second upper electrode film 343 may have a thickness of about 300 to about 1,000 Å measured from an upper face of the first upper electrode film 341.

The upper electrode layer 340 and the ferroelectric layer 335 are thermally treated by an RTP to crystallize materials included in the upper electrode layer 340 and the ferroelectric layer 335. The upper electrode layer 340 and the ferroelectric layer 335 may be treated under an atmosphere including an oxygen gas, a nitrogen gas or a mixture gas of oxygen and nitrogen.

Referring to FIG. 8B, a first hard mask layer and a second hard mask layer are sequentially formed on the second upper electrode film 343. The first hard mask layer may have a thickness of about 100 to about 300 Å measured from an upper face of the second upper electrode film 343, and the second hard mask layer may have a thickness of about 300 to about 1,000 Å based on an upper face of the first hard mask layer. The first hard mask layer may be formed by a sputtering process, a CVD process, an ALD process or a PLD process. The second hard mask layer may be formed by a CVD process, a PECVD process, a PLD process or an ALD process.

After a second photoresist pattern (not shown) is formed on the second hard mask layer, the second and the first hard mask layers are patterned using the second photoresist pattern as an etching mask, thereby forming a hard mask structure 365 on the upper electrode layer 340. The hard mask structure 365 includes a first hard mask 360 and a second hard mask 355 successively formed on the second upper electrode film 343.

The first hard mask 360 may be formed using a material that has a high etching selectivity relative to the first and the second upper electrode films 341 and 342, the ferroelectric layer 335 and the first, the second and the third lower electrode films 320, 325 and 327. For example, the first hard mask 360 is formed using strontium ruthenium oxide (SRO), strontium titanium oxide (STO), lanthanum nickel oxide (LNO), calcium ruthenium oxide (CRO), silicon nitride, silicon oxynitride, etc.

The second hard mask 355 may be also formed using a material that has an etching selectivity with respect to the first hard mask 360, the first and the second upper electrode films 341 and 343, and the ferroelectric layer 335. For example, the second hard mask 355 is formed using undoped polysilicon, silicon oxide, silicon nitride, silicon oxynitride, etc.

After the second photoresist pattern is removed from the second hard mask 355 by an ashing process and/or a stripping process, the second and the first upper electrode films 343 and 341 are sequentially etched using the hard mask structure 360 as an etching mask. Accordingly, an upper electrode 370 is formed on the ferroelectric layer 335. The upper electrode 370 includes a first upper electrode film pattern 373 and a second upper electrode film pattern 371 successively formed on the ferroelectric layer 335 in serial. The upper electrode 370 including the first and the second upper electrode films patterns 373 and 371 may have at least a major sidewall surface, or an entire sidewall surface, inclined by a high angle of about 80 to about 90° with respect to a major adjacent upper surface of the substrate 300 as described above.

Referring to FIG. 8C, the second hard mask 355 is removed from the first hard mask 360 after forming the upper electrode 370 so that only the first hard mask 360 remains on the second upper electrode film pattern 371.

The ferroelectric layer 335 is partially etched at a high temperature using the first hard mask 360 as an etching mask to thereby form a ferroelectric layer pattern 375 on the third lower electrode film 372. In the high temperature etching process of forming the ferroelectric layer pattern 375, the ferroelectric layer pattern 375 may have a sidewall highly inclined by an angle of about 80 to about 90° because the first hard mask 360 may effectively protect the ferroelectric layer pattern 335.

Continuously using the first hard mask 360 as the etching mask, the third lower electrode film 327, the second lower electrode film 325 and the first lower electrode film 320 are sequentially etched, thereby forming a lower electrode 390 on the insulation structure 310 and the pad 315. The lower electrode 390 includes a first lower electrode film pattern 385, a second lower electrode film pattern 380 and a third lower electrode film pattern 377. Each of the first, the second and the third lower electrode film patterns 385, 380 and 377 has a lower portion substantially wider than an upper portion thereof. Since the lower electrode 390 is formed using the first hard mask 360, the lower electrode 390 may have a sidewall inclined by a high angle of about 80 to about 90°.

When the first hard mask 370 is removed from the upper electrode 370, a ferroelectric capacitor 395 is formed over the substrate 300. The ferroelectric capacitor 395 includes the lower electrode 390, the ferroelectric layer pattern 375 and the upper electrode 370. Since the first hard mask 360 includes the material that has the high etching selectivity relative to the ferroelectric layer 335, the third lower electrode film 327, the second lower electrode film 325 and the first lower electrode film 320, the ferroelectric capacitor 395 may have at least a major sidewall surface, or an entire sidewall surface, inclined by a high angle Θ3 of about 80 to about 90° relative to an adjacent major surface of the substrate 300.

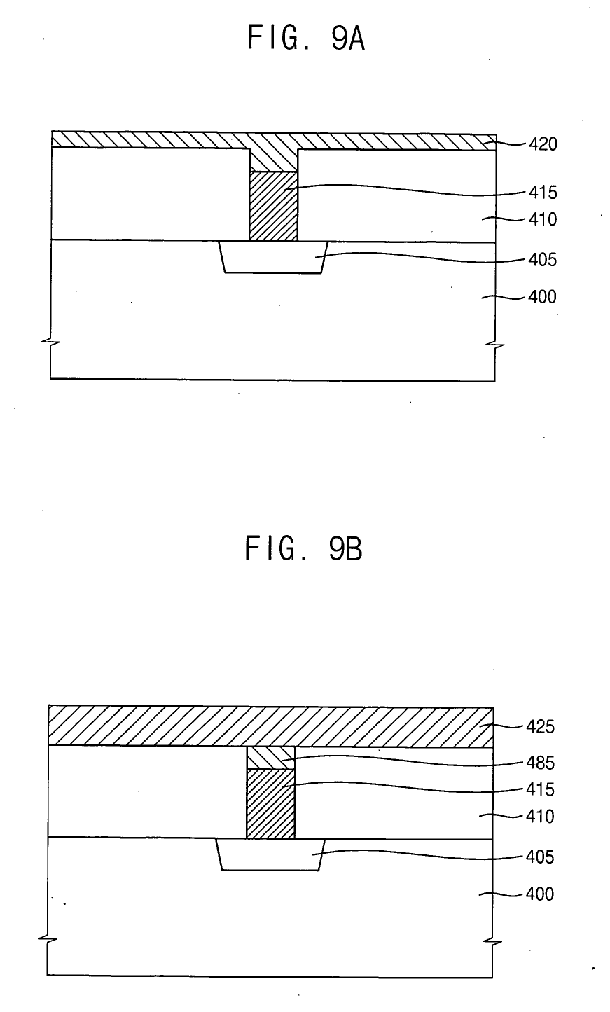

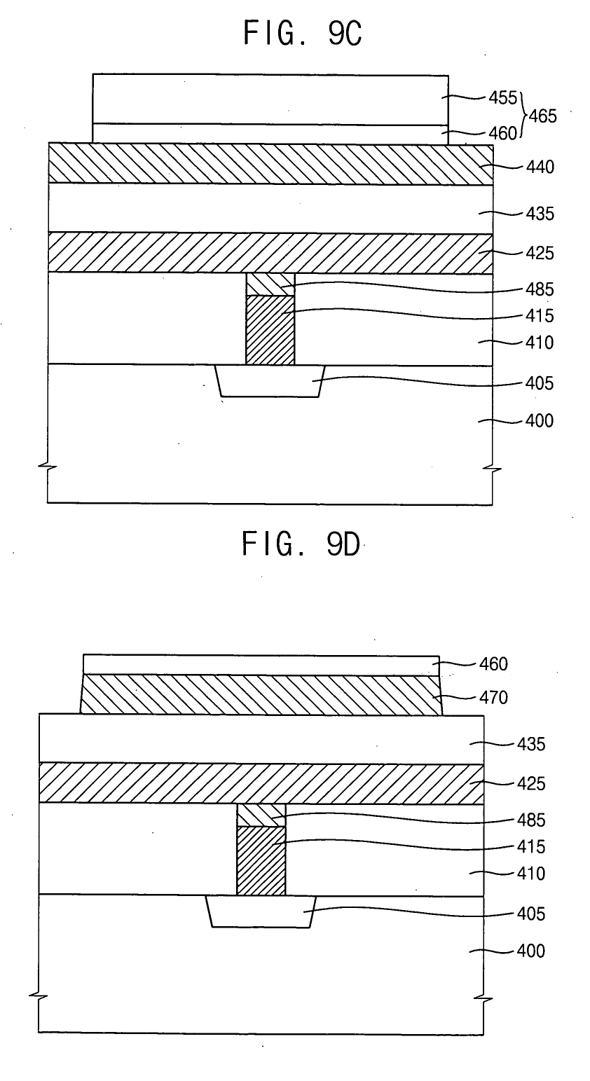

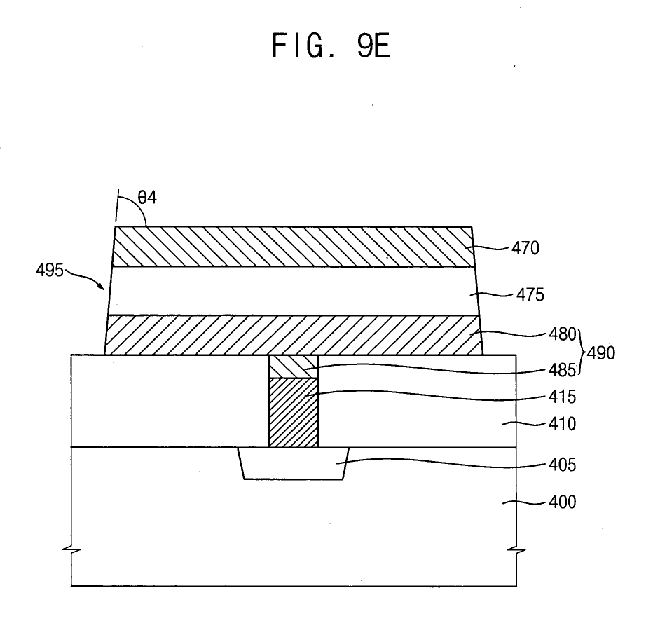

FIGS. 9A to 9E are cross-sectional views illustrating a method of manufacturing a ferroelectric capacitor in accordance with some embodiments of the present invention.

Referring to FIG. 9A, a lower structure 405 is formed on a substrate 400. The substrate 400 may include a silicon wafer, an SOI substrate or a single crystalline metal oxide substrate such as a single crystalline aluminum oxide substrate, a single crystalline strontium titanium oxide substrate or a single crystalline magnesium oxide substrate. The lower structure 405 may include a contact region, a conductive wiring, a conductive pattern, a pad, a plug, a gate structure and/or a transistor, which are formed on or over the substrate 400.

An insulation structure 410 is formed on the substrate 400 to cover the lower structure 405. The insulation structure 410 electrically insulates the lower structure 405 from a lower electrode 490 (see FIG. 9E). The insulation structure 410 may include at least one oxide layer, at least one nitride layer and/or at least one oxynitride layer. The insulation structure 410 may further include at least one insulating interlayer. The insulation structure 410 may be formed using PSG, USG, SOG, FOX, PE-TEOS, HDP-CVD oxide, silicon nitride, silicon oxynitride, etc. Additionally, the insulation structure 410 may be formed by a CVD process, a PECVD process, an ALD process, an HDP-CVD process, etc.

After a hole is formed through the insulation structure 410 by partially etching the insulation structure 410, a conductive layer is formed on the insulation structure 410 to fill up the hole. The conductive layer may be formed using doped polysilicon, a metal or a conductive metal nitride. For example, the conductive layer is formed using tungsten, aluminum, copper, titanium, tungsten nitride, aluminum nitride, titanium nitride, titanium aluminum nitride, etc. The conductive layer may be formed by a sputtering process, a CVD process, an ALD process, a PLD process, etc.

The conductive layer is partially removed by a CMP process and/or an etch back process until the insulation structure 410 is exposed, thereby forming a preliminary pad in the hole. Then, an upper portion of the preliminary pad is removed by an etching process so that a pad 415 is formed in the hole. The pad 415 partially fills up the hole. That is, an upper sidewall of the hole is exposed when the pad 415 is formed in the hole. In an example embodiment of the present invention, the conductive layer may be excessively removed by a CMP process and/or an etch back process to thereby form the pad 415 that partially fills up the hole.

A first lower electrode film 420 is formed on the insulation structure 410 and the pad 415 to completely fill up the hole. The first lower electrode film 420 may be formed using a conductive metal nitride by a CVD process, a sputtering process or an ALD process. For example, the first lower electrode film 420 is formed using titanium aluminum nitride, aluminum nitride, titanium nitride, titanium silicon nitride, tantalum nitride, tantalum silicon nitride and/or tungsten nitride. The first lower electrode film 420 may be advantageously formed using titanium aluminum nitride by the ALD process.

Referring to FIG. 9B, the first lower electrode film pattern 420 is removed by a CMP process and/or an etch back process until the insulation structure 410 is exposed. Hence, a first lower electrode film pattern 485 is formed on the pad 415 to fill up the hole. Namely, the pad 415 and the first lower electrode film pattern 485 completely fill up the hole together. Here, the first lower electrode film pattern 485 positions on the pad 415 only.

A second lower electrode film 425 is formed on the first lower electrode film pattern 485 and the insulation structure 420. The second lower electrode film 425 may have a thickness of about 300 to about 1,000 Å measured from an upper face of the first lower electrode film pattern 485. The second lower electrode film pattern 425 may be formed using a metal such as iridium, platinum, ruthenium, palladium or gold by a sputtering process, a PLD process, a CVD process or an ALD process. The second lower electrode film 425 may be advantageously formed using iridium by the sputtering process. In a formation of the second lower electrode film 425, a reaction chamber in which the substrate 400 is loaded may have a temperature of about 20 to about 350° C. and a pressure of about 3 to about 10 mTorr. Here, the second lower electrode film 425 may be formed under an inactive gas atmosphere include an argon gas, a nitrogen gas and/or a helium gas by applying a power of about 300 to about 1,000W.

Referring to FIG. 9C, a ferroelectric layer 435 is formed on the second lower electrode film 425 by a MOCVD process, a sol-gel process or an ALD process. The ferroelectric layer 435 may have a thickness of about 200 to about 1,200 Å based on an upper face of the second lower electrode film 425. The ferroelectric layer 435 may be formed using a ferroelectric material, a metal oxide having a ferroelectric property or a ferroelectric material doped with calcium, lanthanum, manganese or bismuth. The ferroelectric layer 435 may be advantageously formed using PZT by the MOCVD process. In a formation of the ferroelectric layer 435, a reaction chamber including the substrate 400 may have a temperature of about 350 to about 650° C. and a pressure of about 1 to about 10 Torr.

An upper electrode layer 440 is formed on the ferroelectric layer 435 by a sputtering process, a PLD process, a CVD process or an ALD process. The upper electrode layer 440 may be formed using iridium, platinum, ruthenium, palladium, gold, platinum-manganese alloy, iridium-ruthenium alloy, iridium oxide, strontium ruthenium oxide (SRO), strontium titanium oxide (STO), lanthanum nickel oxide (LNO), calcium ruthenium oxide (CRO), etc. The upper electrode layer 440 may have a thickness of about 100 to about 1,200 Å based on an upper face of the ferroelectric layer 435. In a formation of the upper electrode layer 440, a reaction chamber including the substrate 400 may have a temperature of about 20 to about 350° C. and a pressure of about 3 to about 10 mTorr. Here, the upper electrode 440 may be formed under an inactive gas atmosphere by applying a power of about 300 to about 1,000W.

After the upper electrode layer 440 is formed on the ferroelectric layer 435, the ferroelectric layer 435 and the upper electrode 440 are thermally treated by an RTP to crystallize materials included in the upper electrode layer 440 and the ferroelectric layer 435. The upper electrode layer 440 and the ferroelectric layer 435 may be treated under an atmosphere including an oxygen gas, a nitrogen gas or a mixture gas of oxygen and nitrogen. The upper electrode layer 440 and the ferroelectric layer 435 may be thermally treated at a temperature of about 500 to about 650° C. for about 30 seconds to about 3 minutes.

A first hard mask layer and a second hard mask layer are sequentially formed on the upper electrode layer 440. The first hard mask layer may have a thickness of about 100 to about 300 Å measured from an upper face of the upper electrode layer 440. The first hard mask layer may be formed using a material that has a high etching selectivity relative to the upper electrode layer 440, the ferroelectric layer 435 and the second lower electrode film 425. For example, the first hard mask layer is formed using strontium ruthenium oxide (SRO), strontium titanium oxide (STO), lanthanum nickel oxide (LNO), calcium ruthenium oxide (CRO), silicon oxide, silicon oxynitride, etc. The first hard mask layer may be advantageously formed using strontium ruthenium oxide (SRO). Additionally, the first hard mask layer may be formed by a sputtering process, a CVD process, an ALD process or a PLD process. When the upper electrode layer 440 includes strontium ruthenium oxide (SRO), the first hard mask layer is formed using silicon oxide, silicon oxynitride, strontium titanium oxide (STO), lanthanum nickel oxide (LNO) or calcium ruthenium oxide (CRO). When the upper electrode layer 440 includes iridium, platinum, palladium, gold, platinum-manganese alloy, iridium-ruthenium alloy or iridium oxide, the first hard mask layer is formed using strontium ruthenium oxide (SRO).

The second hard mask layer may have a thickness of about 300 to about 1,000 Å based on an upper face of the first hard mask layer. Thus, a thickness ratio between the first and the second hard mask layers may be in a range of about 1.0:1.0 to about 1.0:10. The second hard mask layer may be formed by a CVD process, a PECVD process, a PLD process or an ALD process. The second hard mask layer may be formed using a material that has a high etching selectivity relative to the first hard mask layer, the upper electrode layer 440 and the ferroelectric layer 435. For example, the second hard mask layer is formed using undoped silicon, silicon oxide, silicon nitride or silicon oxynitride. The second hard mask layer may be advantageously formed using silicon nitride.

After a photoresist pattern (not shown) is formed on the second hard mask layer, the second hard mask layer is patterned using the photoresist pattern as an etching mask, thereby forming a second hard mask 455 on the first hard mask layer.

The photoresist pattern is removed by an ashing process and/or a stripping process, and then the first hard mask layer is partially etched using the second hard mask 455. Hence, a first hard mask 460 is formed on the upper electrode layer 440. As a result, a hard mask structure 465 including the first and the second hard masks 460 and 455 is completed on the upper electrode layer 440. In one example embodiment of the present invention, the second hard mask 460 may have an improved surface by a spin scrubbing process. In an another example embodiment of the present invention, the second and the first hard mask layers may be sequentially etched using the photoresist pattern as an etching mask, thereby forming the hard mask structure 465 on the upper electrode layer 440.

Referring to FIG. 9D, the upper electrode layer 440 is etched using the hard mask structure 465 as an etching mask so that an upper electrode 470 is formed on the ferroelectric layer 435. The upper electrode 470 may have at least a major sidewall surface, or an entire sidewall surface, inclined by an angle of about 80° to about 90° relative to an adjacent major upper surface of the substrate 400. In a formation of the upper electrode 470 using the hard mask structure 465, the second hard mask 455 may be somewhat consumed such that the second hard mask 455 may have a reduced thickness.

The second hard mask 455 is removed from the first hard mask 460. Thus, only the first hard mask 460 remains on the upper electrode 470. In an example embodiment of the present invention, the first hard mask 460 may have a level surface by a spin scrubbing process.

Referring to FIG. 9E, the ferroelectric layer 435 is etched using the first hard mask 460 as an etching mask to thereby form a ferroelectric layer pattern 475 on the second lower electrode film 425. When the ferroelectric layer 435 is etched at a relatively low temperature, the ferroelectric layer pattern 475 may have a sidewall inclined by a relatively low angle. Therefore, the ferroelectric layer 435 is etched at a relatively high temperature of about 200 to about 400° C. to form the ferroelectric layer pattern 475 that has a sidewall inclined by a high angle of about 80 to about 90°. In a formation of the ferroelectric layer pattern 475 at the relatively high temperature, the sidewall of the upper electrode 470 may maintain the inclination angle of about 80 to about 900 because the first hard mask 460 may effectively protect the upper electrode 470.

Continuously using the first hard mask 460 as an etching mask, the second lower electrode film 425 is partially etched to form a second lower electrode film pattern 480 on the first lower electrode film pattern 485 and the insulation structure 410. Therefore, a lower electrode 490 including the first and the second lower electrode film patterns 485 and 480 is completed over the substrate 400.

When the first hard mask 460 is removed from the upper electrode 470, a ferroelectric capacitor 495 is completed over the substrate 400. The ferroelectric capacitor 496 includes the lower electrode 490, the ferroelectric layer pattern 475 and the upper electrode 470. Since the ferroelectric capacitor 495 is formed using the hard mask structure 465 having the first and the second hard masks 460 and 455, the ferroelectric capacitor 495 may have an entire sidewall inclined by a high angle Θ4 of about 80 to about 90°. In particular, since the first and the second hard masks 460 and 455 are effectively protect the upper electrode 470 and the ferroelectric layer pattern 475 in long etching processes for forming the ferroelectric capacitor 495, the upper electrode 470 and the ferroelectric layer patterns 475 maintain the high inclination angles of about 80 to about 90°. Therefore, the ferroelectric capacitor 495 may have an enlarged effective area. Additionally, etched damage to the ferroelectric layer pattern 475 and a deterioration of the ferroelectric layer pattern 475 may be prevented because the first hard mask 460 effectively protects the ferroelectric layer pattern 475. Hence, a leakage current from the ferroelectric layer pattern 475 may be sufficiently reduced.

Methods of Manufacturing a Semiconductor Device

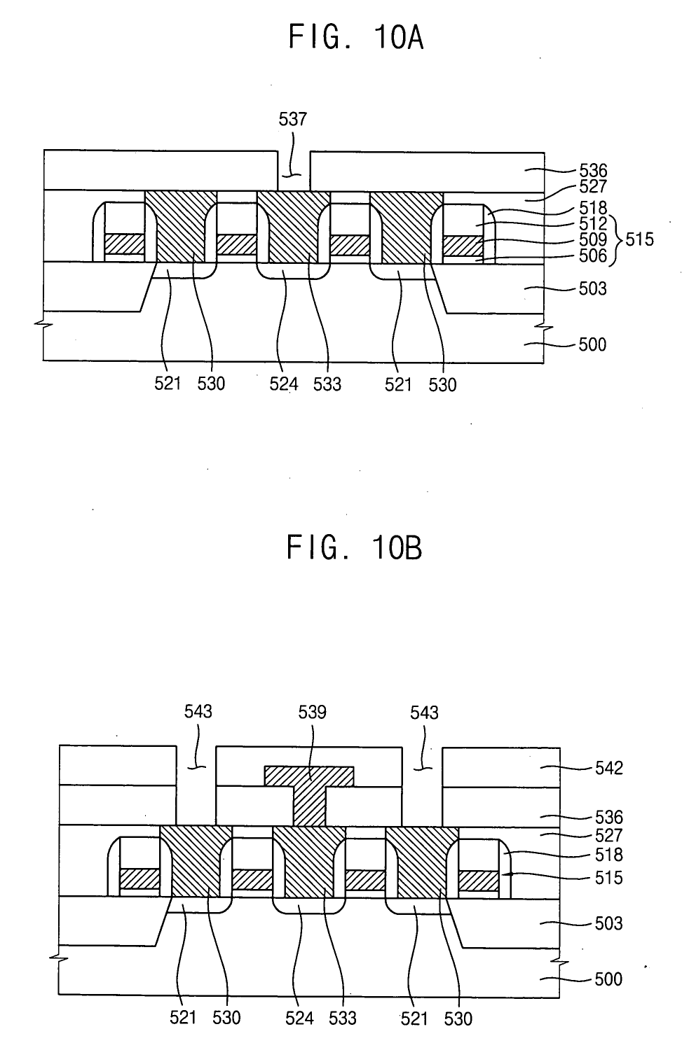

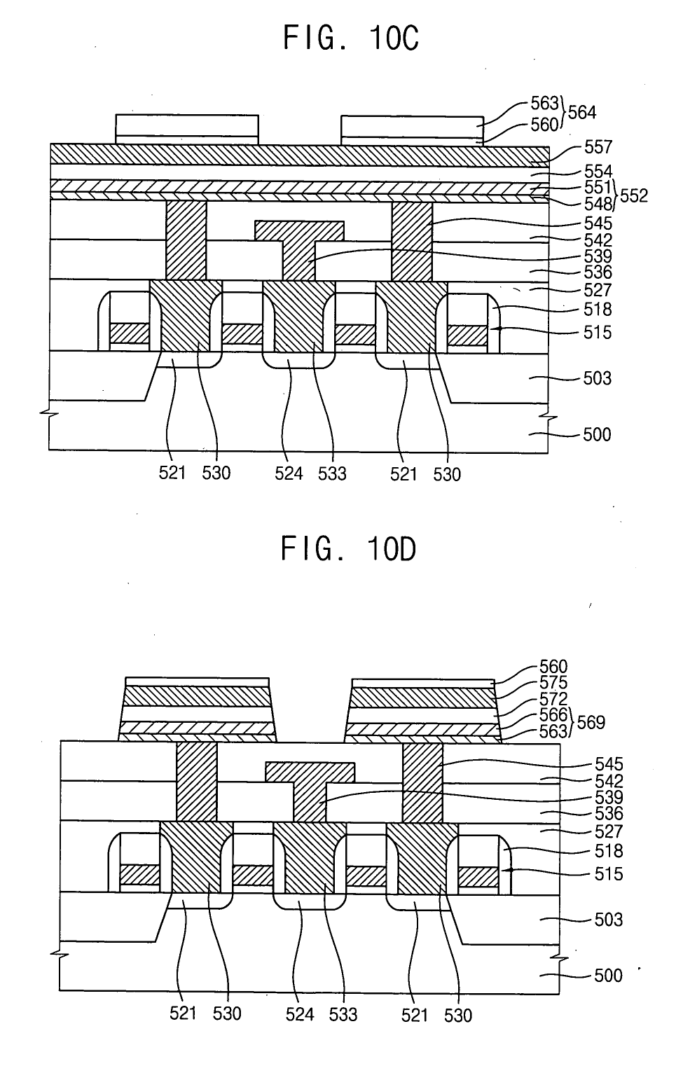

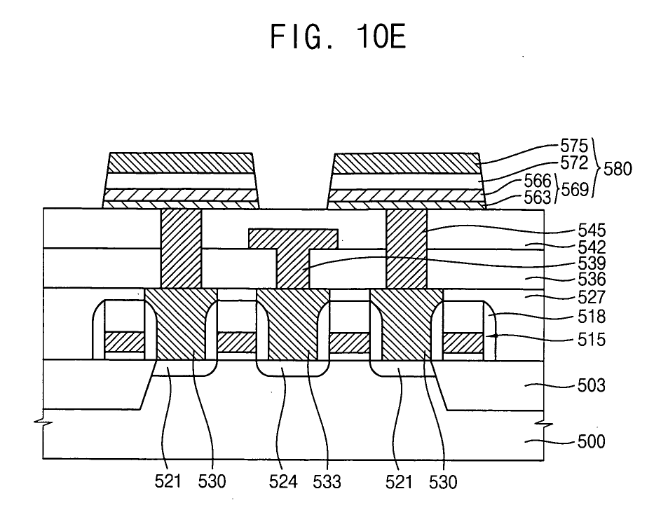

FIGS. 10A to 10E are cross-sectional views illustrating a method of manufacturing a semiconductor device in accordance with some embodiments of the present invention.

Referring to FIG. 10A, an isolation layer 503 is formed at an upper portion of a semiconductor substrate 500 to define an active region and a field region of the semiconductor substrate 500. The isolation layer 503 may be formed by an isolation process such as a shallow trench isolation (STI) process.

A thin gate insulation layer is formed on the substrate 500. The gate insulation layer may be formed by a thermal oxidation process or a CVD process.

A first conductive layer and a first mask layer are sequentially formed on the thin gate insulation layer. The first conductive layer may be formed using polysilicon doped with impurities. The first mask layer may be formed using a material that has an etching selectivity relative to a material of a first insulating layer 527 successively formed. For example, the first mask layer includes a nitride such as silicon nitride when the first insulating layer 527 includes an oxide.

After a first photoresist pattern (not shown) is formed on the first mask layer, the first mask layer, the first conductive layer and the thin gate insulation layer are partially etched using the first photoresist pattern as an etching mask. Thus, gate structures 515 are formed on the substrate 500. Each of the gate structures 515 includes a gate insulation layer pattern 506, a gate conductive layer pattern 509 and a gate mask pattern 512 sequentially formed on the substrate 500.

In an example embodiment of the present invention, the first mask layer is patterned using the first photoresist pattern as an etching mask so that the gate mask pattern 512 is formed on the first conductive layer. After the first photoresist pattern is removed by an ashing process and/or a stripping process, the first conductive layer and the gate insulation layer are etched using the gate mask pattern 512 as an etching mask. Hence, the gate structure 515 including a gate insulation layer pattern 506, the gate conductive layer pattern 509 and the gate mask pattern 512 is formed on the substrate 500.

After a first insulation layer is formed on the substrate 500 to cover the gate structures 515, the first insulation layer is anisotropically etched to form gate spacers 518 on sidewalls of the gate structures 515. The gate spacers 518 may be formed using a nitride such as silicon nitride.

Referring now to FIG. 10A, impurities are implanted into portions of the substrate 500 exposed between the gate structures 515 by an ion implantation process using the gate structures 515 as ion implantation masks. Hence, a first contact region 521 and a second contact region 524 are formed at the exposed portions of the substrate 500. The first and the second contact regions 521 and 524 may correspond to a source region and a drain region of a transistor. Additionally, the first contact region 521 and the second contact region 524 may correspond to a capacitor contact region and a bit line contact region. Particularly, a first pad 530 for a ferroelectric capacitor 580 (see FIG. 10E) makes contact with the first contact region 521 whereas a second pad 533 for a bit line 539 (see FIG. 10B) makes contact with the second contact region 524. As a result, the transistors are completed on the substrate 500. Each of the transistors includes the gate structure 515, the gate spacer 518, the first contact region 521 and the second contact region 524.

In an example embodiment of the present invention, first impurities may be implanted into the exposed portions of the substrate 500 with a low concentration before forming the gate spacer 518 on the sidewall of the gate structure 515. After forming the gate spacer 518 on the sidewall of the gate structure 515, second impurities are implanted into the exposed portions of the substrate 500 to thereby form the first and the second contact regions 521 and 524 having lightly doped drain (LDD) structures, respectively.

The first insulating interlayer 527 is formed on the substrate 500 to cover the gate structures 515 using an oxide. For example, the first insulating interlayer 527 is formed using BPSG, PSG, SOG, FOX, TEOS, PE-TEOS, USG, HDP-CVD oxide, etc. The first insulating interlayer 527 may be formed by a CVD process, a PECVD process, an HDP-CVD process, an ALD process, etc.

An upper portion of the first insulating interlayer 527 is partially removed by a CMP process and/or an etch back process to planarize the first insulating interlayer 527. In one example embodiment of the present invention, the first insulating interlayer 527 may have a height higher than that of the gate structure 515. In another example embodiment of the present invention, the first insulating interlayer 527 may have a height substantially the same as that of the gate structure 515 when the first insulating interlayer 527 is planarized until the gate structure 515 is exposed.

After a second photoresist pattern (not shown) is formed on the first insulating interlayer 527, the first insulating interlayer 527 is partially etched using the second photoresist pattern as an etching mask. Hence, first contact holes are formed through the first insulating interlayer 527 to expose the first and the second contact regions 521 and 524, respectively. In an example embodiment of the present invention, the first contact holes may be formed by partially etching the first insulating interlayer 527 using an etching gas that has a high etching selectivity between the first insulating interlayer 527 and the gate spacer 518. Therefore, the first contact holes may be self-aligned relative to the gate structures 515. Some first contact holes expose the first contact regions 521 corresponding to a capacitor contact region, whereas other first contact hole exposes the second contact region 524 corresponding to a bit line contact region.

After the second photoresist pattern is removed by an ashing process and/or a stripping process, a second conductive layer is formed on the first insulating interlayer 527 to fill up the first contact holes. The second conductive layer may be formed using metal or polysilicon doped with impurities.

The second conductive layer is partially removed by a CMP process and/or an etch back process until the first insulating interlayer 527 is exposed so that the first pad 530 and the second pad 533 are formed in the first contact holes. Since the first contact holes are formed by the above self-alignment process, the first and the second pads 530 and 533 may also correspond to self-alignment contact (SAC) pads. The first pad 530 is positioned on the first contact region 521 corresponding to the capacitor contact region. The second pad 533 is formed on the second contact region 524 corresponding to the bit line contact region. That is, the first and the second pads 530 and 533 make contact with the first and the second contact regions 521 and 524, respectively.

A second insulating interlayer 536 is formed on the first insulating interlayer 527. The second insulating interlayer 536 may electrically isolate the first pad 530 from the bit line 539 successively formed. The second insulating interlayer 536 may be formed using BPSG, PSG, SOG, FOX, USG, TEOS, PE-TEOS, HDP-CVD oxide, etc. The second insulating interlayer 536 may be formed by a CVD process, a PECVD process, an ALD process, an HDP-CVD process, etc. In one example embodiment of the present invention, the second insulating interlayer 536 may be formed using an oxide substantially the same as that of the first insulating interlayer 527. In another example embodiment of the present invention, the second insulating interlayer 536 may include an oxide different from that of the first insulating interlayer 527.

The second insulating interlayer 536 is planarized by partially removing the second insulating interlayer 536 through a CMP process and/or an etch back process.

After a third photoresist pattern (not shown) is formed on the second insulating interlayer 536, the second insulating interlayer 536 is partially etched using the third photoresist pattern as an etching mask. Thus, a second contact hole 537 is formed though the second insulating interlayer 536 to expose the second pad 533 buried in the first insulating interlayer 527.

Referring to FIG. 10B, the third photoresist pattern is removed by an ashing process and/or a stripping process, and then a third conductive layer is formed on the second insulating interlayer 536 to fill up the second contact hole 527.

After a fourth photoresist pattern (not shown) is formed on the third conductive layer, the third conductive layer is etched using the fourth photoresist pattern as an etching mask so that the bit line 539 filling up the second contact hole 537 is formed on the second insulating interlayer 536. The bit line 539 may include a first film of metal/metal nitride and a second film of metal. For example, the first film includes titanium/titanium nitride (Ti/TiN) and the second film includes tungsten (W).

A third insulating interlayer 542 is formed on the second insulating interlayer 536 to cover the bit line 539 by a CVD process, a PECVD process, an HDP-CVD process, an ALD process, etc. The third insulating interlayer 542 may be formed using BPSG, PSG, SOG, FOX, USG, TEOS, PE-TEOS, HDP-CVD oxide, etc. The third insulating interlayer 542 may be formed using an oxide substantially the same as or different from that of the second insulating interlayer 536 and/or the first insulating interlayer 527. In an example embodiment of the present invention, the third insulating interlayer 542 may be formed using the HDP-CVD oxide at a relatively low temperature because the HDP-CVD oxide may sufficiently fill up a gap between the bit lines 539.

The third insulating interlayer 542 is planarized by partially removing an upper portion of the third insulating interlayer 542 through a CMP process and/or an etch back process. In an example embodiment of the present invention, an additional insulation layer of a nitride may be formed on the bit line 539 and the second insulating interlayer 536 in order to form a void in a portion of the third insulating interlayer 542 between adjacent bit lines 539, and then the third insulating interlayer 542 may be formed on the additional insulation layer. After a fifth photoresist pattern (not shown) is formed on the third insulating interlayer 542, the third insulating interlayer 542 and the second insulating interlayer 536 are partially etched using the fifth photoresist pattern as an etching mask. Thus, third contact holes 543 are formed through the third insulating interlayer 542 and the second insulating interlayer 527 to expose the first pads 530. In an example embodiment of the present invention, a cleaning process may be performed about the substrate 500 having the resultant structure so as to remove a native oxide layer and/or particles from the first pads 530 after forming the third contact holes 543.

Referring to FIG. 10C, after a fourth conductive layer is formed on the third insulating interlayer 542 to fill up the third contact holes 543, the fourth conductive layer is partially removed by a CMP process and/or an etch back process until the third insulating interlayer 542 is exposed. Hence, third pads 545 are formed in the third contact holes 543. The third pad 545 may be formed using polysilicon doped with impurities. The third pad 545 electrically connects the first pad 530 to a lower electrode 569 (see FIG. 10D) successively formed. Thus, the lower electrode 569 is electrically connected to the first contact region 521 through the third pad 545 and the first pad 530.

A first lower electrode film 548 and a second lower electrode film 551 are sequentially formed on the third pads 545 and the third insulating interlayer 542. The first lower electrode film 548 may have a thickness of about 50 to about 300 Å, and the second lower electrode film 551 may have a thickness of about 300 to about 1,000 Å. Hence, a lower electrode layer 552 including the first and the second lower electrode films 548 and 551 is formed on the third pad 545 and the third insulating interlayer 542. The first lower electrode film 548 may be formed using a metal nitride by a CVD process, a sputtering process, an ALD process, a PLD process, etc. The second lower electrode film 551 may be formed using a metal by a sputtering process, a CVD process, a PLD process, an ALD process, etc.

A ferroelectric layer 554 is formed on the second lower electrode film 551 to have a thickness of about 200 to about 1,000 Å. The ferroelectric layer 554 may be formed using a ferroelectric material, a ferroelectric material doped with a metal or a metal oxide having a ferroelectric property. The ferroelectric layer 554 may be formed by a MOCVD process, a sol-gel process, an ALD process, etc. In an example embodiment of the present invention, a third lower electrode film may be formed on the second lower electrode film 551 before forming the ferroelectric layer 554. The third lower electrode film may have a thickness of about 10 to about 500 Å. The third lower electrode film may include strontium ruthenium oxide (SRO), strontium titanium oxide (STO) or calcium ruthenium oxide (CRO) doped with a metal such as copper, lead or bismuth. The third lower electrode film may be formed at a temperature of about 20 to about 350° C. and a pressure of about 3 to about 10 mTorr under an inactive gas atmosphere by applying a power of about 300 to about 1,000W.

An upper electrode layer 557 is formed on the ferroelectric layer 554 to have a thickness of about 10 to about 1,200 Å. The upper electrode layer 557 may be formed by a sputtering process, a CVD process, an ALD process, a PLD process, etc. The upper electrode layer 557 may be formed using iridium, platinum, ruthenium, palladium, gold, platinum-manganese alloy, iridium-ruthenium alloy, iridium oxide, strontium ruthenium oxide (SRO), strontium titanium oxide (STO), lanthanum nickel oxide (LNO), calcium ruthenium oxide (CRO), etc. For example, the upper electrode layer 557 may be formed at a temperature of about 20 to about 350° C. and a pressure of about 3 to about 10 mTorr under an inactive gas atmosphere by applying a power of about 300 to about 1,000W.

After forming the upper electrode layer 557, the ferroelectric layer 554 and the upper electrode layer 557 are thermally treated under an oxygen gas atmosphere, a nitrogen gas atmosphere or a mixture gas of oxygen and nitrogen atmosphere. Hence, materials in the ferroelectric layer 554 and the upper electrode layer 557 are crystallized. The ferroelectric layer 554 and the upper electrode layer 557 may be treated by a rapid thermal process (RTP).

Referring now to FIG. 10C, a first hard mask layer and a second hard mask layer are sequentially formed on the upper electrode layer 557. The first hard mask layer may be formed by a sputtering process, a CVD process, an ALD process or a PLD process. The first hard mask layer may have a thickness of about 100 to about 300 Å. The first hard mask layer may be formed using a material that has an etching selectivity relative to those of the upper electrode layer 557, the ferroelectric layer 554 and the lower electrode layer 552. For example, the first hard mask is formed using strontium ruthenium oxide (SRO), strontium titanium oxide (STO), lanthanum nickel oxide (LNO), calcium ruthenium oxide (CRO), silicon nitride, silicon oxynitride, etc.

The second hard mask layer may be formed by a CVD process, a PECVD process, a PLD process or an ALD process. The second hard mask layer may have a thickness of about 300 to about 1,000 Å. The second hard mask layer may be formed using a material that has an etching selectivity with respect to those of the first hard mask, the upper electrode layer 557 and the ferroelectric layer 554. For example, the second hard mask layer is formed using undoped polysilicon, silicon oxide, silicon nitride, silicon oxynitride, etc.

After a sixth photoresist pattern (not shown) is formed on the second hard mask layer, the second hard mask is partially etched using the sixth photoresist pattern as an etching mask. Thus, a second hard mask 563 is formed on the first hard mask layer.

The sixth photoresist pattern is removed by an ashing process and/or a stripping process, and then the first hard mask layer is etched using the second hard mask 563 as an etching mask, thereby forming a first hard mask 560 on the upper electrode layer 557. As a result, a hard mask structure 564 including the second and the first hard masks 563 and 560 is completed on the upper electrode layer 557. In one example embodiment of the present invention, the second hard mask 563 may have an improved surface by a spin scrubbing process. In another example embodiment of the present invention, the second and the first hard mask layers may be sequentially etched using the sixth photoresist pattern as an etching mask, thereby forming the hard mask structure 564 on the upper electrode layer 557.

Referring to FIG. 10D, the upper electrode layer 557 is etched using the hard mask structure 564 as an etching mask so that an upper electrode 575 on the ferroelectric layer 554. The upper electrode 575 may have at least a major sidewall, or an entire sidewall, inclined by a high angle of about 80 to about 90° relative to an adjacent major upper surface of the substrate 500.

The second hard mask 563 is removed from the first hard mask 560. As described above, the first hard mask 560 may have a level surface by a spin scrubbing process.

Using the first hard mask 560 as an etching mask, the ferroelectric layer 554 is etched at a relatively high temperature so that the ferroelectric layer pattern 572 may have a sidewall inclined by a high angle of about 80 to about 90°. In a formation of the ferroelectric layer pattern 572, since the first hard mask 560 may effectively protect the upper electrode 575, the upper electrode 575 may maintain the highly inclined sidewall.

The second lower electrode film 551 and the first lower electrode film 548 are successively etched continuously using the first hard mask 560 to thereby form a lower electrode 569 on the third insulating interlayer 542 and the third pad 545.

Referring to FIG. 10E, the first hard mask 560 is removed from the upper electrode 575 so that a ferroelectric capacitor 580 is formed over the substrate 500. The ferroelectric capacitor 580 includes the lower electrode 569, the ferroelectric layer pattern 572 and the upper electrode 575. Since the ferroelectric capacitor 580 is formed using the hard mask structure 564 including the first and the second hard masks 560 and 563, the ferroelectric capacitor 580 may have at least a major sidewall surface, or an entire sidewall surface, inclined by a high angle of about 80 to about 90° relative to an adjacent major upper surface of the substrate 500.

When an additional insulating interlayer and an upper wiring may be formed on the ferroelectric capacitor 580, the semiconductor device such as an FRAM device is formed on the substrate 500.

According to the present invention, an upper electrode, a ferroelectric layer and a lower electrode are formed using a hard mask structure including a first hard mask and a second hard mask. Thus, the ferroelectric capacitor may have an enlarged effective area caused by a sidewall thereof inclined by a high angle. The ferroelectric capacitor may have an enhanced data sensing margin so that the ferroelectric capacitor may have improved ferroelectric characteristics such as a high data retention or polarization retention. Additionally, since the hard mask structure may effectively prevent damage to the ferroelectric layer pattern, the ferroelectric capacitor may have improved electrical characteristics by reducing a leakage current. When a semiconductor device such as an FRAM device includes the ferroelectric capacitor, the semiconductor device may have an enhanced reliability.

The foregoing is illustrative of the present invention and is not to be construed as limiting thereof. Although a few example embodiments of the present invention have been described, those skilled in the art will readily appreciate that many modifications are possible in the exemplary embodiments without materially departing from the novel teachings and advantages of the present invention. Accordingly, all such modifications are intended to be included within the scope of the present invention as defined in the claims. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a ferroelectric capacitor, comprising:
forming a lower electrode layer on a substrate, the lower electrode layer comprising at least one lower electrode film;
forming a ferroelectric layer on the lower electrode layer;
forming an upper electrode layer on the ferroelectric layer;
forming a hard mask structure on the upper electrode layer, the hard mask structure comprising a first hard mask and a second hard mask; and
partially etching the upper electrode layer, the ferroelectric layer, and the lower electrode layer using the hard mask structure as an etching mask to respectively form an upper electrode, a ferroelectric layer pattern, and a lower electrode.

2. The method of claim 1, wherein forming the hard mask structure comprises:
forming a first hard mask layer on the upper electrode layer;
forming a second hard mask layer on the first hard mask layer; and
forming the first and the second hard masks on the upper electrode layer by partially etching the respective first and the second hard mask layers.

3. The method of claim 2, wherein the first hard mask layer is formed using a material that has an etching selectivity relative to the upper electrode layer.

4. The method of claim 3, wherein the second hard mask layer is formed using a material that has an etching selectivity relative to the first hard mask layer, the upper electrode layer, and the ferroelectric layer.

5. The method of claim 4, wherein partially etching the upper electrode layer, the ferroelectric layer, and the lower electrode layer using the hard mask structure as the etching mask comprises:
partially etching the first hard mask layer and the upper electrode layer using the second hard mask as an etching mask; and
partially etching the ferroelectric layer and the lower electrode layer using the first hard mask as an etching mask.

6. The method of claim 2, wherein the first hard mask layer is formed using at least one selected from the group consisting of strontium ruthenium oxide (SRO), strontium titanium oxide (STO), lanthanum nickel oxide (LNO), calcium ruthenium oxide (CRO), silicon nitride, and silicon oxynitride.

7. The method of claim 2, wherein the first hard mask layer is formed by a sputtering process, a chemical vapor deposition (CVD) process, an atomic layer deposition (ALD) process, or a pulse laser deposition (PLD) process.

8. The method of claim 2, wherein the second hard mask layer is formed using at least one selected from the group consisting of silicon nitride, silicon oxide, polysilicon, and silicon oxynitride.

9. The method of claim 2, wherein the second hard mask layer is formed by a CVD process, an ALD process, a PLD process, or a plasma enhanced chemical vapor deposition (PECVD) process.

10. The method of claim 2, wherein a thickness ratio between the first hard mask layer and the second hard mask layer is about 1:1 to about 1:10.

11. The method of claim 2, further comprising removing the second hard mask layer after forming the upper electrode and before partially etching the ferroelectric layer to form the ferroelectric layer pattern.

12. The method of claim 1, wherein at least a major sidewall surface of the ferroelectric capacitor is inclined by an angle of about 80 to about 90° relative to a major adjacent upper surface of the substrate.

13. The method of claim 1, wherein forming the lower electrode layer comprises:
forming a first lower electrode film on the substrate; and
forming a second lower electrode film on the first lower electrode film.

14. The method of claim 13, wherein the first lower electrode film is formed using at least one selected from the group consisting of titanium aluminum nitride, aluminum nitride, titanium nitride, titanium silicon nitride, tantalum nitride and tantalum silicon nitride, and the second lower electrode film is formed using at least one selected from the group consisting of iridium, platinum, ruthenium, palladium and gold.

15. The method of claim 13, wherein forming the lower electrode layer further comprises forming a third lower electrode film on the second lower electrode film.

16. The method of claim 15, wherein the third lower electrode film is formed using at least one selected from the group consisting of strontium ruthenium oxide (SRO), strontium titanium oxide (STO), lanthanum nickel oxide (LNO) and calcium ruthenium oxide (CRO).

17. The method of claim 1, prior to forming the lower electrode layer the method further comprising:
forming an insulation structure on the substrate;
forming a hole through the insulation structure exposing a portion of the substrate; and
forming a pad that at least partially fills the hole.

18. The method of claim 17, wherein forming the lower electrode layer comprises:
forming a first lower electrode film on the pad that completely fills the hole; and
forming a second lower electrode film on the first lower electrode film and the insulation structure.

19. The method of claim 1, wherein the ferroelectric layer is formed using at least one selected from the group consisting of PZT[(Pb, Zr)TiO₃], SBT(SrBi₂Ta₂O₉), BLT[(Bi, La)TiO₃], PLZT[Pb(La, Zr)TiO₃], BST[(Ba, Sr)TiO₃], PZT doped with at least one of calcium, lanthanum, manganese, and bismuth, SBT doped with at least one of calcium, lanthanum, manganese, and bismuth, BLT doped with at least one of calcium, lanthanum, manganese, and bismuth, PLZT doped with at least one of calcium, lanthanum, manganese, and bismuth, and BST doped with at least one of calcium, lanthanum, manganese, and bismuth.

20. The method of claim 1, wherein the upper electrode layer is formed using at least one selected from the group consisting of iridium, platinum, ruthenium, platinum-manganese alloy, iridium-ruthenium alloy, iridium oxide, strontium ruthenium oxide (SRO), strontium titanium oxide (STO), lanthanum nickel oxide (LNO), and calcium ruthenium oxide (CRO).

21. The method of claim 1, wherein forming the upper electrode layer comprises:
forming a first upper electrode film on the ferroelectric layer; and
forming a second upper electrode film on the first upper electrode film.

22. The method of claim 21, wherein:
the first upper electrode film is formed using at least one selected from the group consisting of strontium ruthenium oxide (SRO), strontium titanium oxide (STO), lanthanum nickel oxide (LNO), and calcium ruthenium oxide (CRO); and
the second upper electrode film is formed using at least one selected from the group consisting of iridium, platinum, ruthenium, palladium, and gold.

23. A method of manufacturing a semiconductor device, comprising:
forming a lower structure on a substrate;
forming an insulation structure on the lower structure;
forming a pad contacting the lower structure through the insulation structure;
forming a lower electrode layer on the pad and the insulation structure wherein the lower electrode includes at least one lower electrode film;
forming a ferroelectric layer on the lower electrode layer;
forming an upper electrode layer on the ferroelectric layer;
forming a hard mask structure on the upper electrode layer wherein the hard mask structure comprises a first hard mask and a second hard mask; and
partially etching the upper electrode layer, the ferroelectric layer, and the lower electrode layer using the hard mask structure as an etching mask to respectively form an upper electrode, a ferroelectric layer pattern and a lower electrode.

24. The method of claim 23, wherein forming the hard mask structure comprises:
forming a first hard mask layer on the upper electrode layer;
forming a second hard mask layer on the first hard mask layer; and
forming the first and the second hard masks on the upper electrode layer by partially etching the respective first and the second hard mask layers.

25. The method of claim 24, wherein:
the first hard mask layer is formed using a material that has an etching selectivity relative to the upper electrode layer; and
the second hard mask layer is formed using a material that has an etching selectivity relative to the first hard mask layer, the upper electrode layer, and the ferroelectric layer.

26. The method of claim 25, wherein partially etching the upper electrode layer, the ferroelectric layer, and the lower electrode layer using the hard mask structure as the etching mask comprises:
partially etching the first hard mask layer and the upper electrode layer using the second hard mask as an etching mask; and
partially etching the ferroelectric layer and the lower electrode layer using the first hard mask as an etching mask.

27. The method of claim 24, wherein the first hard mask layer is formed using at least one selected from the group consisting of strontium ruthenium oxide (SRO), strontium titanium oxide (STO), lanthanum nickel oxide (LNO), calcium ruthenium oxide (CRO), silicon nitride, and silicon oxynitride; and
the second hard mask layer is formed using at least one selected from the group consisting of silicon nitride, silicon oxide, polysilicon, and silicon oxynitride.

28. The method of claim 24, wherein the first hard mask layer is formed by a sputtering process, a chemical vapor deposition (CVD) process, an atomic layer deposition (ALD) process, or a pulse laser deposition (PLD) process; and
the second hard mask layer is formed by a CVD process, an ALD process, a PLD process, or a plasma enhanced chemical vapor deposition (PECVD) process.

29. The method of claim 24, further comprising removing the second hard mask after forming the upper electrode and before partially etching the ferroelectric layer to form the ferroelectric layer pattern.

30. The method of claim 23, wherein a thickness ratio between the first hard mask and the second hard mask is in a range of about 1.0:1.0 to about 1.0:10.

31. The method of claim 23, wherein forming the lower electrode layer comprises:
forming a first lower electrode film on the pad and the insulation structure; and
forming a second lower electrode film on the first lower electrode film.

32. The method of claim 31, wherein forming the lower electrode layer further comprises forming a third lower electrode film on the second lower electrode film.

33. The method of claim 23, wherein forming the pad comprises:
forming a hole exposing the lower structure by partially etching the insulation structure;
forming a conductive layer on the insulation structure to fill the hole; and
forming the pad to at least partially fill the hole by partially removing the conductive layer.

34. The method of claim 33, wherein forming the lower electrode layer comprises:
forming a first lower electrode film to completely fill the hole; and
forming a second lower electrode film on the first lower electrode film and the insulation structure.

35. The method of claim 23, wherein forming the upper electrode layer comprises:
forming a first upper electrode film on the ferroelectric layer; and
forming a second upper electrode film on the first upper electrode film.
